(19) United States
(12) Patent Application Publication
(10) Pub. No.: US 2026/0040613 A1
(43) Pub. Date: Feb. 5, 2026

(54) GATE TRENCH POWER SEMICONDUCTOR DEVICES HAVING DEEP CHANNEL REGIONS AND RELATED METHODS OF FABRICATING SAME

(71) Applicant: Wolfspeed, Inc., Durham, NC (US)

(72) Inventors: Woongsun Kim, Cary, NC (US); Naeem Islam, Fuquay-Varina, NC (US); Ping-Ju Chuang, Morrisville, NC (US); Sei-Hyung Ryu, Cary, NC (US)

(21) Appl. No.: 18/788,395

(22) Filed: Jul. 30, 2024

(51) Int. Cl. H01L 29/78; H01L 29/16

(52) U.S. Cl. CPC H10D 30/668; H10D 30/665; H10D 62/8325

(57) ABSTRACT

A semiconductor device comprises a semiconductor layer structure that comprises a drift layer having a first conductivity type, a first well region having a second conductivity type, a second well region having the second conductivity type and a JFET region having the first conductivity type, where the JFET region has a doping concentration that is higher than a doping concentration of the drift layer. A gate trench is provided in the semiconductor layer structure. The first well region forms a first sidewall of the gate trench and the second well region forms a second sidewall of the gate trench. Additionally, first and second sidewalls of the JFET region are aligned with respective first and second sidewalls of the gate trench.

### FIELD OF THE INVENTION

The present invention relates to power semiconductor devices and, more particularly, to gate trench power semiconductor devices.

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region and a drain region that each have a first conductivity type are formed in the semiconductor layer structure and are separated from each other by a channel region that has a second conductivity type. A gate electrode is disposed adjacent the channel region and separated from the channel region by a thin oxide layer. A MOSFET may be turned on or off by setting a bias voltage that is applied to the gate electrode to be above or below a threshold value. When a MOSFET is turned on (i.e., it is in its “on-state”), current is conducted through the channel region between the source and drain regions. When the bias voltage is reduced below the threshold level, the current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type conductivity, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT.

In many applications, MOSFETs may need to carry large currents and/or be capable of blocking high voltages (e.g., hundreds or thousands of volts of electric potential). Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power MOSFETs and other power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate may be on the top surface of the semiconductor layer structure and the drain may be on the bottom surface of the semiconductor layer structure).

The semiconductor layer structure of a power semiconductor device includes an “active region” in which one or more functional semiconductor devices are formed. The active region acts as a main junction for blocking voltage during reverse bias (off-state) operation and for providing current flow during forward bias (on-state) operation. The power semiconductor device may also have an edge termination structure such as guard rings or a junction termination extension in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the resultant structure may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

Vertical gate-controlled power semiconductor devices can have a planar gate electrode design in which the gate electrodes are formed on top of the semiconductor layer structure or, alternatively, may have the gate electrodes formed within gate trenches in the semiconductor layer structure, which are typically referred to as gate trench devices. With the planar gate electrode design, the channel region of each unit cell transistor is horizontally disposed underneath the gate electrode. In contrast, in gate trench devices, the channels are typically vertically disposed adjacent sidewalls of the gate electrodes. Gate trench devices may provide enhanced performance, but typically require a more complicated manufacturing process.

One failure mechanism for a power MOSFET is the so-called “breakdown” of the gate oxide layer. The gate oxide layer is subjected to high electric fields during normal device operation. The stress on the gate oxide layer caused by these electric fields generates defects in the oxide material, and these defects build up over time. When the concentration of defects reaches a critical value, a so-called “percolation path” may be created through the gate oxide layer that electrically connects the gate electrode to the source region, thereby creating a short-circuit that can destroy the device. The “lifetime” of a gate oxide layer (i.e., how long the device can be operated before breakdown occurs) is a function of, among other things, the magnitude of the electric field that the gate oxide layer is subjected to and the length of time for which the electric field is applied. FIG. 1 is a schematic graph illustrating the relationship between the operating time until breakdown occurs (the “gate oxide lifetime”) and the level of the electric field applied to the gate oxide layer. This graph assumes that the same electric field is always applied (which is not necessarily the case). As shown in FIG. 1, the relationship may, in some cases, be generally linear when the gate oxide lifetime is plotted on a logarithmic scale. The important point to take from FIG. 1 is that as the electric field level is increased, the lifetime of the gate oxide layer decreases exponentially. The lifetime of the gate oxide layer may be increased by increasing the thickness of the gate oxide layer, but various performance parameters of a MOSFET may be a function of the thickness of the gate oxide layer and thus increasing the thickness of the gate oxide layer is typically not an acceptable way of increasing the lifetime of the gate oxide layer.

### SUMMARY

Pursuant to some embodiments of the present invention, semiconductor device are provided that comprise a semiconductor layer structure that comprises a drift layer having a first conductivity type, where an upper portion of the drift layer comprises a JFET region having the first conductivity type, where the JFET region has a doping concentration that is higher than a doping concentration of a lower portion of the drift layer; and a gate trench that has a first sidewall and a second siedewall in the semiconductor layer structure. In addition, first and second sidewalls of the JFET region are aligned with respective first and second sidewalls of the gate trench.

In some embodiments, the semiconductor device further comprises a first well region having a second conductivity type that comprises a first portion of the first sidewall of the gate trench and a second well region having the second conductivity type that comprises a first portion of the second sidewall of the gate trench. The first well region and the second well region may each extend deeper into the semiconductor layer structure than the gate trench. In some embodiments, the first and second well regions have substantially planar lower surfaces.

In some embodiments, the JFET region extends deeper into the semiconductor layer structure than the first well region and extends deeper into the semiconductor layer structure than the second well region.

In some embodiments, the first well region comprises a first channeled ion implant well region and the second well region comprises a second channeled ion implant well region.

In some embodiments, the first well region comprises a first deep well region that extends at least as deep into the semiconductor layer structure as the gate trench and a first shallow well region that is laterally adjacent the first deep well region and that does not extend as deep into the semiconductor layer structure as the first deep well region. In some embodiments, a peak doping concentration of the first deep well region is greater than a peak doping concentration of the first shallow well region.

In some embodiments, the semiconductor layer structure further comprises a trench shield having the second conductivity type below the gate trench, wherein the first and second well regions extend deeper into the semiconductor layer structure than the trench shield.

In some embodiments, the drift layer comprises a silicon carbide drift layer. In some embodiments, the semiconductor device comprises a metal oxide semiconductor field effect transistor (“MOSFET”).

In some embodiments, the first well region and the second well region are part of a continuous well region and the gate trench is one of a plurality of gate trenches that appear as islands in the semiconductor layer structure when the semiconductor device is viewed from above, and wherein the continuous well region forms sidewalls of each of the gate trenches.

In some embodiments, the JFET region forms at least a portion of a bottom of the gate trench.

Pursuant to further embodiments of the present invention, semiconductor device are provided that comprise a semiconductor layer structure that comprises a drift layer having a first conductivity type; a gate trench that has a first sidewall and an opposed second sidewall in the semiconductor layer structure; a gate oxide layer in the gate trench; and a well region that comprises a channel region. The channel region extends at least as deep into the semiconductor layer structure as the gate trench, and the gate oxide layer directly contacts the drift region underneath outer portions of a bottom of the gate trench.

In some embodiments, a lower surface of the well region has a substantially constant depth. In some embodiments, the well region comprises a first channeled ion implant well region.

In some embodiments, an upper portion of the drift layer structure further comprises a JFET region underneath the first gate trench. The JFET region has the first conductivity type and a doping concentration that is higher than a doping concentration of a lower portion of the drift layer. Sidewalls of the JFET region are aligned with sidewalls of the gate trench. In some embodiments, the JFET region extends deeper into the semiconductor layer structure than the well region.

In some embodiments, the semiconductor layer structure further comprises a trench shield having the second conductivity type underneath the gate trench, wherein the well region extends deeper into the semiconductor layer structure than the trench shield.

In some embodiments, the first well region comprises a first channeled ion implant well region and the second well region comprises a second channeled ion implant well region the drift layer comprises a silicon carbide drift layer, and the semiconductor device comprises a metal oxide semiconductor field effect transistor (“MOSFET”).

In some embodiments, the well region is part of a continuous well region and the gate trench is one of a plurality of gate trenches that appear as islands in the semiconductor layer structure when the semiconductor device is viewed from above, and wherein the continuous well region forms sidewalls of each of the gate trenches.

Pursuant to additional embodiments of the present invention, semiconductor device are provided that comprise a semiconductor layer structure; and a gate trench in the semiconductor layer structure. The semiconductor layer structure comprises a drift layer having a first conductivity type, where an upper portion of the drift layer comprises a JFET region having the first conductivity type and a doping concentration that is higher than a doping concentration of a lower portion of the drift layer. First and second sidewalls of the JFET region are aligned with respective first and second sidewalls of the gate trench.

In some embodiments, the semiconductor layer structure further comprises a first well region and a second well region that each extend deeper into the semiconductor layer structure than the gate trench. In some embodiments, the first and second well regions have substantially planar lower surfaces. In some embodiments, the JFET region extends deeper into the semiconductor layer structure than the first well region and extends deeper into the semiconductor layer structure than the second well region. In some embodiments, the first well region comprises a first channeled ion implant well region and the second well region comprises a second channeled ion implant well region.

In some embodiments, the semiconductor layer structure comprises a first well region comprises a first deep well region that extends at least as deep into the semiconductor layer structure as the gate trench and a first shallow well region that is laterally adjacent the first deep well region and that does not extend as deep into the semiconductor layer structure as the first deep well region. In some embodiments, a peak doping concentration of the first deep well region is greater than a peak doping concentration of the first shallow well region.

In some embodiments, the semiconductor layer structure further comprises a trench shield having the second conductivity type below the gate trench, wherein the first and second well regions extend deeper into the semiconductor layer structure than the trench shield.

Pursuant to further embodiments of the present invention, methods of forming a semiconductor device are provided in which a semiconductor layer structure is provided that comprises a drift layer having a first conductivity type. A gate trench is formed in the semiconductor layer structure. An ion implantation mask is then formed in the gate trench. A second conductivity type well region is formed in the semiconductor layer structure via ion implantation using the mask in the gate trench as an ion implantation mask.

In some embodiments, the well region extends deeper into the semiconductor layer structure than the gate trench.

In some embodiments, a depth of a lower surface of the well region may be substantially constant.

In some embodiments, forming the well region in the semiconductor layer structure that has the second conductivity type via ion implantation comprises forming the well region in the semiconductor layer structure using a channeled ion implantation process. In some embodiments, the semiconductor layer structure comprises silicon carbide and the ion implantation mask comprises a material other than silicon carbide. In some embodiments, an implantation energy of the channeled ion implantation process is selected so that the ion implantation mask in the gate trench will substantially prevent implanted dopant ions from passing into the portion of the semiconductor layer structure underneath the gate trench.

In some embodiments, forming the gate trench in the semiconductor layer structure may comprise forming a mask layer on the semiconductor layer structure; pattering the mask layer to provide a patterned mask; and forming the gate trench in the semiconductor layer structure using the patterned mask as an etch mask. The method may further comprise implanting first conductivity type dopants into the semiconductor layer structure to form a JFET region underneath the gate trench, the JFET region having a first conductivity type and a doping concentration that is higher than a doping concentration of a lower portion of the drift layer. In some embodiments, sidewalls of the JFET region are aligned with sidewalls of the gate trench. In some embodiments, the JFET region is formed before the ion implantation mask is formed. In some embodiments, the ion implantation mask comprises a second ion implantation mask, and wherein implanting first conductivity type dopants into the semiconductor layer structure to form the JFET region underneath the gate trench comprises implanting first conductivity type dopants into the semiconductor layer structure to form the JFET region underneath the gate trench using the mask as a first ion implantation mask. In some embodiments, the JFET region extends deeper into the semiconductor layer structure than the well region.

In some embodiments, forming the ion implantation mask in the gate trench may comprise conformally forming a mask layer on an upper surface of the semiconductor layer structure; and planarizing the mask layer.

In some embodiments, the method may further comprise forming a trench shield having the second conductivity type underneath the gate trench. In some embodiments, the well region extends deeper into the semiconductor layer structure than the trench shield.

In some embodiments, the drift layer comprises a silicon carbide drift layer.

In some embodiments, the semiconductor device comprises a metal oxide semiconductor field effect transistor (“MOSFET”).

Pursuant to still other embodiments of the present invention, methods of forming a semiconductor device are provided in which a semiconductor layer structure is provided that comprises a drift layer having a first conductivity type. A first mask layer is formed on the semiconductor layer structure. The first mask layer is then patterned to provide a first patterned mask. A plurality of gate trenches are formed in the semiconductor layer structure using the first patterned mask as an etch mask. Finally, first conductivity type dopants are implanted into the semiconductor layer structure to form a plurality of JFET regions underneath the respective gate trenches, each JFET region having a first conductivity type and a doping concentration that is higher than a doping concentration of a lower portion of the drift layer.

In some embodiments, sidewalls of each JFET region are aligned with sidewalls of a respective one of the gate trenches.

In some embodiments, implanting first conductivity type dopants into the semiconductor layer structure to form the plurality of JFET regions underneath the respective gate trenches comprises implanting first conductivity type dopants into the semiconductor layer structure to form the JFET regions underneath the respective gate trenches using the first patterned mask as a first ion implantation mask.

In some embodiments, the method may further comprise forming a second patterned mask that is in each of the gate trenches; and forming at least one well region in the semiconductor layer structure that has a second conductivity type via ion implantation using the second patterned mask as a second ion implantation mask. In some embodiments, the at least one well region extends deeper into the semiconductor layer structure than the gate trenches. In some embodiments, forming the at least one well region in the semiconductor layer structure that has the second conductivity type via ion implantation comprises forming the at least one well region in the semiconductor layer structure using a channeled ion implantation process. In some embodiments, each well region of the at least one well region has a substantially planar lower surface. In some embodiments, the JFET regions extend deeper into the semiconductor layer structure than the at least one well region. In some embodiments, the JFET regions are formed before the second patterned mask is formed. In some embodiments, forming the second patterned mask in the gate trenches may comprise conformally forming a mask layer on an upper surface of the semiconductor layer structure; and planarizing the mask layer to form the second patterned mask.

In some embodiments, the method may further comprise forming trench shields having the second conductivity type underneath the respective gate trenches. In some embodiments, at least one well region extends deeper into the semiconductor layer structure than the trench shields. In some embodiments, the trench shields extend deeper into the semiconductor layer structure than the at least one well region. In some embodiments, forming the trench shields having the second conductivity type underneath the respective gate trenches comprises forming a conformal mask pattern in the gate trenches and forming the trench shields by ion implantation through the conformal mask pattern.

### BRIEF DESCRIPTION OF THE DRAWINGS

FIG. 1 is a semi-log graph illustrating the relationship between the lifetime of the gate oxide layer as a function of applied electric field strength.

FIG. 2 is a cross-sectional view of a unit cell of a conventional gate trench power MOSFET.

FIG. 3A is a schematic top view of a gate trench silicon carbide power MOSFET according to certain embodiments of the present invention and also shows the bond wires that can be used to connect the gate and source pads to external circuits.

FIG. 3B is a schematic top view of the power MOSFET of FIG. 3A with an upper protective layer omitted to show the full gate and source metallization.

FIG. 3C is a schematic top view of the power MOSFET of FIG. 3A with the upper protective layer, the source metallization and an intermetal dielectric layer omitted to show the gate electrodes.

FIG. 3D is an enlarged view of the portion of FIG. 3C in the box labelled 3D.

FIG. 3E is a schematic cross-sectional view taken along line 3E-3E of FIG. 3D with the intermetal dielectric layer and source metallization that are omitted in FIGS. 3C-3D added for context.

FIGS. 4A-4H are a series of schematic cross-sectional diagrams that illustrate a method of fabricating the power MOSFET of FIGS. 3A-3E.

FIG. 5 is a schematic cross-sectional view of a gate trench silicon carbide power MOSFET according to further embodiments of the present invention that is taken along a line equivalent to line 3E-3E of FIG. 3D.

FIGS. 6A-6B are schematic cross-sectional diagrams that illustrate certain steps of a method of fabricating the power MOSFET of FIG. 5.

FIGS. 7A-7B are schematic cross-sectional diagrams that illustrate certain steps of an alternative method of fabricating the power MOSFET of FIG. 5.

FIG. 8 is a schematic cross-sectional view of a gate trench silicon carbide power MOSFET according to additional embodiments of the present invention that is taken along a line equivalent to line 3E-3E of FIG. 3D.

FIG. 9 is a schematic cross-sectional diagram that illustrates certain steps of a method of fabricating the power MOSFET of FIG. 8.

FIG. 10 is a schematic cross-sectional view of a gate trench silicon carbide power MOSFET according to other embodiments of the present invention that is taken along a line equivalent to line 3E-3E of FIG. 3D.

FIG. 11 is a schematic cross-sectional view of a gate trench silicon carbide power MOSFET according to still further embodiments of the present invention that is taken along a line equivalent to line 3E-3E of FIG. 3D.

FIGS. 12A-12F are a series of schematic cross-sectional diagrams that illustrate certain steps of a method of fabricating the power MOSFET of FIG. 10.

FIG. 13 is a schematic cross-sectional view of a gate trench silicon carbide power MOSFET according to yet additional embodiments of the present invention that is taken along a line equivalent to line 3E-3E of FIG. 3D.

FIG. 14 is a schematic cross-sectional view of a gate trench silicon carbide power MOSFET according to still other embodiments of the present invention that is taken along a line equivalent to line 3E-3E of FIG. 3D.

FIG. 15 is a flow chart of a method of fabricating a semiconductor device according to certain embodiments of the present invention.

FIG. 16 is a flow chart of a method of fabricating a semiconductor device according to further embodiments of the present invention.

FIG. 17 is a plan view of the semiconductor layer structure of a power MOSFET that is a cell configuration version of the power MOSFET of FIGS. 3A-3E.

Two-part reference numerals that include two numbers separated by a dash (−) are sometimes used in the figures and the discussion that follows to identify instances of multiple like elements. The full reference number may be used to refer to individual instances of the like element while the first part of the reference number may be used to refer to the like elements collectively.

It will be appreciated that the sizes (e.g., the thicknesses) of various regions in the drawings are not drawn to scale to allow enlargement of other regions of the drawings.

### DETAILED DESCRIPTION

Vertical silicon carbide based gate trench power semiconductor devices such as vertical power MOSFETs and IGBTs are attractive for many applications due to their inherent low specific on-resistance, which may result in more efficient operation for power switching operations. The channels in a gate trench vertical power device are formed in the sidewalls of the gate trenches, and hence are vertical channels. The carrier mobility in these vertically-oriented sidewall channels may be about 2-4 times higher than the corresponding carrier mobility in the horizontal channel of a standard planar gate (i.e., non-gate trench) vertical power device, which results in increased current density during on-state operation allowing for higher switching speeds. The gate trench design also reduces the overall pitch of the device, which increases device integration. The lower conduction losses (due to the reduced on-state resistance) and improved switching speeds make gate trench power devices particularly well-suited for high frequency power applications having low to moderate voltage blocking requirements (e.g., 600-1200 Volts). These devices may have reduced requirements for associated passive components and require relatively simple cooling schemes. As MOSFETs are the most widely used silicon carbide based gate trench power semiconductor devices, the discussion below focuses on MOSFET embodiments. It will be appreciated, however, that each of the described embodiments may alternatively be implemented using non-oxide gate dielectric layers (e.g., nitrides, high dielectric constant materials, etc.), and that the same techniques may be used to form other gate trench power semiconductor devices such as IGBTs, gate-controlled thyristors and the like.

As discussed above, gate trench power MOSFETs are susceptible to oxide reliability issues due to the presence of high electric fields in the gate oxide layers that line the bottoms and sidewalls of the gate trenches. The high electric fields degrade the gate oxide layer over time, and may eventually result in failure of the device. When gate trench MOSFETs operate in reverse blocking operation (i.e., when the MOSFET is in its off-state), the source terminal of the MOSFET is typically grounded, the gate terminal is typically grounded or at a negative bias voltage, and the drain terminal is typically at a high positive voltage. During such reverse blocking operations, high electric fields extend upwardly from the drain terminal (which is on the lower surface of the semiconductor layer structure) toward the upper surface of the semiconductor layer structure. Thus, under reverse blocking operation, the portions of the gate oxide layers lining the bottoms of the gate trenches experience the highest electric field levels. Due to electric field crowding effects, the electric field levels in the lower “corners” of the gate oxide layer at the bottom edges of the gate trench may be particularly high (i.e., the portions of the gate oxide layers that cover the region where the sidewalls of the gate trenches merge into the bottoms of the respective gate trenches). Moreover, due to the difference in permittivity between silicon carbide and silicon oxide, the electric field in a silicon oxide gate oxide layer may be about 2.6 times higher than the electric field in the silicon carbide semiconductor layer structure adjacent the gate oxide layer. Breakdown of the silicon oxide occurs when the electric field reaches a critical level. In order to avoid such breakdown, power MOSFETs may be operated with the drain voltage at lower levels during reverse blocking operation to ensure that the electrical field does not reach a level that will result in breakdown. In other words, the voltage rating of a power MOSFET may be set to ensure that premature gate oxide breakdown will not occur.

So-called “trench shields” (also called “bottom shields”) are often provided underneath the gate trenches of gate trench power MOSFETs in order to reduce the electric field levels in the bottom portion of the gate oxide layer during reverse blocking operation. These trench shields are formed by doping the portions of the semiconductor layer structure underneath the gate trenches with dopants having the same conductivity type as the dopants included in the channel regions of the device. The trench shields are typically formed via one or more ion implantation processes in which p-type dopant ions (for an n-type MOSFET) are implanted through the bottom surfaces of the gate trenches. The trench shields may, for example, extend downwardly 0.5 to 1.0 microns or more from the bottoms of the gate trenches into the semiconductor layer structure of the device, and are moderately to highly doped regions. The trench shields are electrically connected to the source terminal of the MOSFET by p-type trench shield connection patterns. A variety of different trench shield connection patterns are known in the art, and any suitable trench shield connection pattern design may be used with the power semiconductor devices according to embodiments of the present invention.

Gate trench power MOSFETs may further include additional shielding regions that are referred to as “support shields.” The support shields are formed in the semiconductor layer structure between adjacent gate trenches and, like the trench shields, may comprise moderately or highly doped semiconductor regions having the same conductivity type as the channel regions of the MOSFET. The support shields may, for example, extend to the same depth in the semiconductor layer structure as the trench shields and may be formed by a high-energy ion implantation process. The support shields may directly connect to the source metallization in the active region of the device.

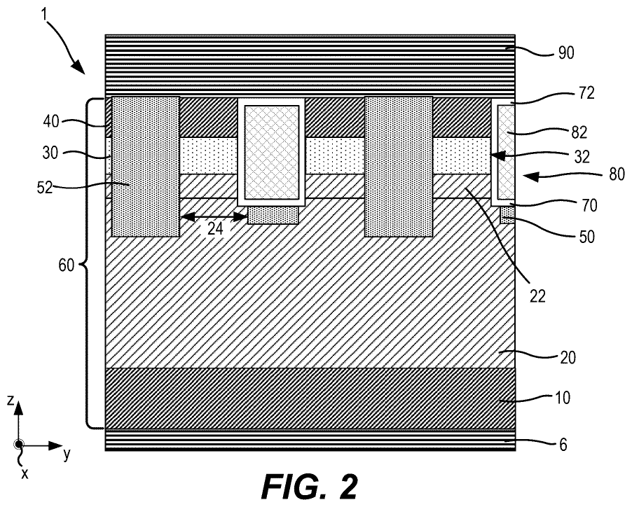

FIG. 2 is a cross-sectional view of a unit cell of a known silicon carbide power MOSFET 1 that includes support shields. The MOSFET 1 includes a semiconductor layer structure 60 that has first and second major surfaces that extend in the x-direction and the y-direction of an x-y-z coordinate system. The semiconductor layer structure 60 has a thickness in the z-direction, which is also referred to herein as the depth direction. The cross-sectional view of FIG. 2 is taken perpendicular to the x-direction. Thus, the vertical axis in FIG. 2 is the depth direction. The MOSFET 1 includes a plurality of gate trenches 80, which have longitudinal axes that run in the x-direction, so the y-direction in FIG. 2 is also referred to as the lateral direction, which is the width direction of the gate trenches 80.

As shown in FIG. 2, the semiconductor layer structure 60 of MOSFET 1 includes a plurality of semiconductor layers and regions that have different conductivity types and doping concentrations. Some or all of these layers and regions may comprise silicon carbide layers/regions. As noted above, a plurality of gate trenches 80 are formed in the upper portion of the semiconductor layer structure 60. Only one full gate trench 80 and a part of a second gate trench 80 are shown in FIG. 2.

The semiconductor layer structure 60 includes a silicon carbide semiconductor substrate 10. The silicon carbide semiconductor substrate 10 may be heavily-doped with n-type dopants. The semiconductor substrate 10 may be a thick layer (e.g., 50 microns or more). A lightly-doped n-type (n⁻) silicon carbide drift region 20 is provided on the upper surface of the substrate 10. The drift region 20 may also be a thick layer (e.g., several microns or tens of microns) and hence only a portion of the drift region 20 is shown in FIG. 2. Herein, the “drift region” may also be referred to as a “drift layer” and it will be appreciated that the two terms are synonymous. A plurality of n-type silicon carbide JFET regions 22 are formed in the upper portion of the drift region 20. The JFET regions 22 may be more heavily doped than the remainder of the drift region 20. The JFET regions 22 are typically formed by forming a continuous more heavily-doped (as compared to the remainder of the drift region 20) JFET layer via epitaxial growth. Subsequent trench etch and ion implantation processes (discussed below) may then be performed that divide the JFET layer into the plurality of JFET regions 22.

Several different types of p-type regions are formed in the semiconductor layer structure 60 via ion implantation, including p-type wells 30 (also referred to as “p-wells”), p-type trench shields 50 and p-type support shields 52. The p-wells 30 may be moderately-doped p-type regions that are provided on the upper surfaces of the respective n-type JFET regions 22. The p-type trench shields 50 are moderately or heavily doped p-type regions that are formed underneath the respective gate trenches 80, and may extend underneath the respective gate trenches 80. The p-type support shields 52 extend downwardly from an upper portion (e.g., the upper surface) of the semiconductor layer structure 60 in between a pair of adjacent gate trenches 80. The p-type support shields 52 may be moderately doped p-type silicon carbide regions that are formed using one or more high energy ion implantation steps. The support shields 52 may extend deeper into semiconductor layer structure 60 than the trench shields 50.

The JFET regions 22 are formed in the upper portion of the drift region 20. The drift region 20 may have an n-type doping concentration as grown of, for example, about 1×10¹⁶ dopants/cm³ or 2×10¹⁶ dopants/cm³. The JFET regions 22 are formed by ion implantation, and have a peak doping concentration that may be, for example, between twice and ten times the doping concentration of the remainder of the drift region 20. The gaps 24 that are defined between adjacent trench shields 50 and support shields 52 are referred to as “JFET gaps” 24, and may be formed in the JFET regions 22 and/or below the JFET regions 22, depending upon the design of the JFET regions 22. Finally, heavily-doped (n⁺) n-type silicon carbide source regions 40 are formed on upper portions of the p-wells 30, typically by ion implantation.

The substrate 10, drift region 20, JFET regions 22, p-wells 30, source regions 40, trench shields 50 and support shields 52 may form the semiconductor layer structure 60 of the MOSFET 1.

A gate oxide layer 70 is formed conformally within each gate trench 80, and gate electrodes 82 are formed in the respective gate trenches 80 on the gate oxide layers 70. An intermetal dielectric pattern 72 covers the gate electrodes 82. A source metallization 90 is formed on the intermetal dielectric pattern 72 and on the heavily-doped n-type source regions 40 and upper portions of the support shields 52. A metal drain contact 6 is formed on the lower surface of the substrate 10.

The p-type trench shields 50 and the p-type support shields 52 act to suppress the electric fields in the upper portion of the semiconductor layer structure 60 during reverse blocking operation, thereby lowering the electric fields in the gate oxide layers 70, which improves the reliability of power MOSFET 1. Unfortunately, however, the addition of the support shields 52 increases the “pitch” of power MOSFET 1 (i.e., the distance between adjacent unit cells in the y-direction, which is the lateral distance between unit cells), since the support shields 52 are added to each unit cell of power MOSFET 1.

Pursuant to some embodiments of the present invention, gate trench power semiconductor devices are provided that have improved designs. The gate trench power semiconductor devices according to embodiments of the present invention have deep well regions that extend deeper into the semiconductor layer structure than the gate trenches. As a result, in these embodiments, the JFET gaps may be located exclusively underneath the gate trenches. Since deep well regions are provided, the need for support shields may be eliminated. This allows the pitch of the power semiconductor device to be reduced. Moreover, since the JFET gaps are located exclusively underneath the gate trenches, the pitch may be further reduced. Thus, while the JFET gaps in the power semiconductor devices according to some embodiments of the present invention may have narrower JFET gaps than most conventional devices, the pitch of these power semiconductor devices may be reduced significantly, which means that the on-state current that flows through each JFET gap may be reduced since the number of unit cells is increased. As such, the power semiconductor devices according to embodiments of the present invention may maintain good on-state resistance performance while supporting higher blocking voltages.

While the provision of deep well regions can eliminate the need for support shields, it may be challenging to form such deep p-wells in a cost effective manner and/or without causing significant damage to the semiconductor layer structure. According to some embodiments of the present invention, the deep well regions may be formed using a channeled ion implantation process. As described for example, in U.S. Pat. No. 11,075,264, the entire content of which is incorporated herein by reference, a channeled ion implantation process refers to an ion implantation process in which the ions are implanted at an angle that corresponds to channels within the crystal lattice of the semiconductor layer structure where no atoms are present. Many of the dopant ions will thus be implanted along these channels, allowing the dopant ions to be implanted much deeper into the crystal lattice as they are not deflected by atoms near the surface. Moreover, the deep well regions may be formed after the gate trenches are formed in the upper surface of the semiconductor layer structure. An ion implantation mask may be formed in the gate trenches, and the dopant ions may be blanket implanted into the upper layer of the semiconductor layer structure to form the deep p-wells. Since a channeled ion implantation process is used, many of the dopant ions used to form the deep p-wells will be implanted along channels in the crystal lattice of the semiconductor material, allowing for a deep implant using relatively low ion implantation energies. The mask material that is deposited in the gate trenches (e.g., silicon oxide, polysilicon, etc.) will not have channels along the axis of implantation, and hence the dopant ions will not implant as deeply into the mask material. As such, well regions that are deeper than the gate trenches may be formed using the channeled ion implantation while at the same time ensuring that dopant ions are not implanted into the semiconductor layer structure below the gate trenches (since the ion implantation energy will not be sufficient to implant dopant ions through the mask). Moreover, this process self-aligns the well regions with the gate trenches.

Pursuant to further embodiments of the present invention, power semiconductor devices are provided that have JFET regions that are selectively formed in the semiconductor layer structure underneath the gate trenches using ion implantation. In some embodiments, the JFET regions may be formed using the etch mask that is used during the gate trench etching process as an ion implantation mask, thereby avoiding the need for any extra masking steps. Moreover, since the JFET regions are formed using the same mask used to etch the gate trenches in the semiconductor layer structure, the JFET regions may be self-aligned with the gate trenches. The JFET regions may increase the conductivity at the bottoms of the channel portions of the well regions, which may reduce the on-state resistance of the power semiconductor device.

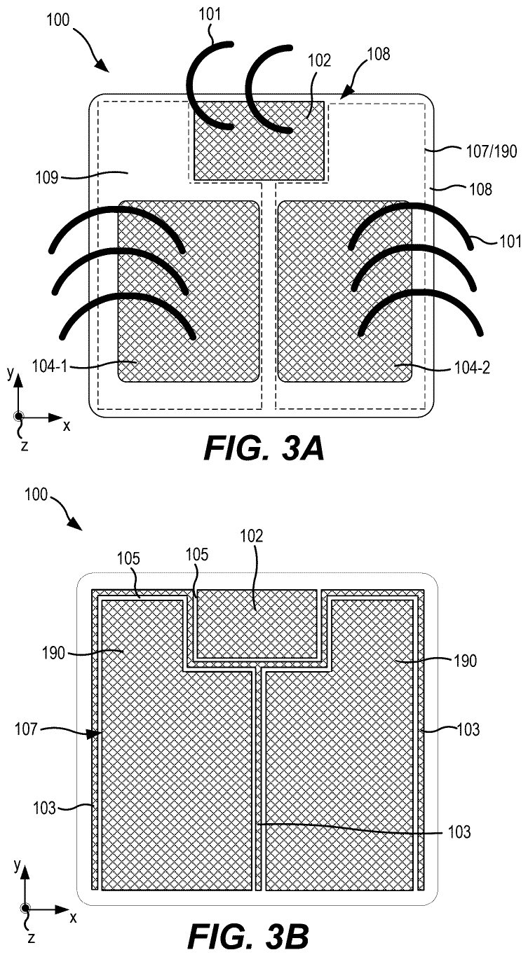

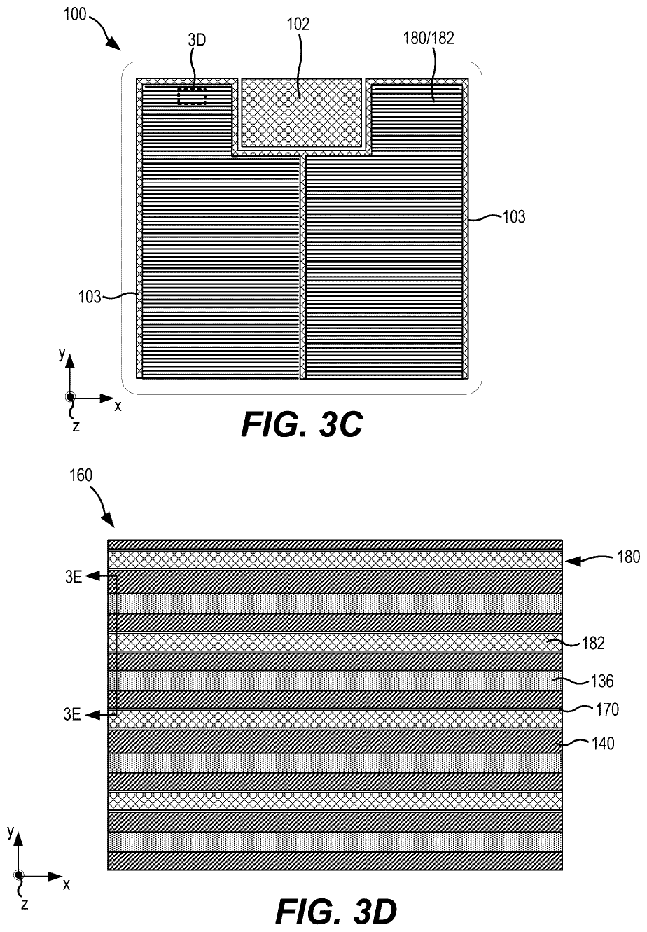

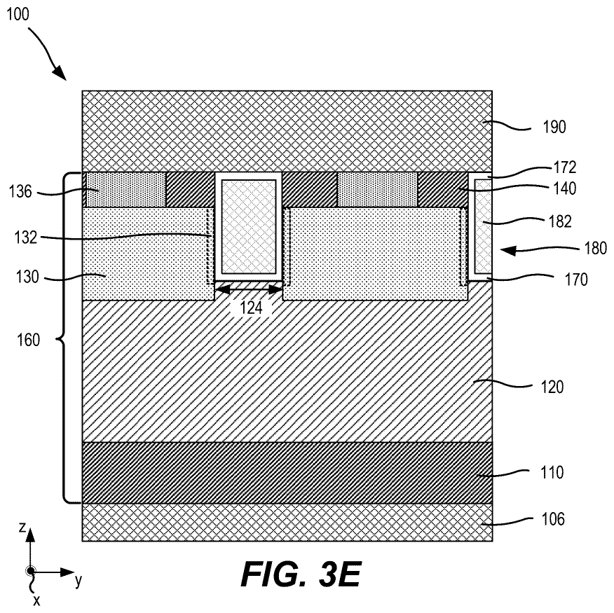

Embodiments of the present invention will now be described in more detail with reference to FIGS. 3A-17. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate controlled thyristors and the like.

FIG. 3A is a schematic top view of a gate trench silicon carbide power MOSFET 100 according to certain embodiments of the present invention. FIG. 3B is a schematic plan view of the power MOSFET 100 with an upper protective layer omitted to show the full gate and source metallization. FIG. 3C is a schematic top view of power MOSFET 100 with the upper protective layer, the source metallization and an intermetal dielectric layer omitted to show the gate electrodes. As will be discussed below with reference to various cross-sectional views, power MOSFET 100 includes a semiconductor layer structure 160 (see FIGS. 3D-3E) that comprises a plurality of semiconductor layers/regions. At least one of the semiconductor layers in the semiconductor layer structure 160 may be a silicon carbide layer. Various metal and/or dielectric layers are formed on either side of the semiconductor layer structure 160 and embedded in the semiconductor layer structure 160.

Referring now to FIG. 3A, power MOSFET 100 includes a gate pad 102 and one or more source pads 104-1, 104-2 that are each formed on the upper side of the semiconductor layer structure 160. A metal drain pad 106 (see FIGS. 3D-3E) is provided on the bottom side of the semiconductor layer structure 160. The gate pad 102, the source pads 104 and the drain pad 106 form the respective gate, source and drain terminals of power MOSFET 100. The gate and source pads 102, 104 may each be formed of a metal, such as aluminum, that bond wires can be readily attached to via conventional techniques such as thermo-compression or soldering. The drain pad 106 may likewise be a metal pad. A protective layer 109 such as a polyimide layer may cover the entire upper surface of power MOSFET 100 except for the gate and source pads 102, 104.

Still referring to FIG. 3A, the power MOSFET 100 includes a source metallization 190 (indicated by the dashed boxes in FIG. 3A) that electrically connects certain regions of the semiconductor layer structure 160 to the source pads 104-1, 104-2. The source metallization 190 may include, for example, an ohmic contact layer (e.g., a metal silicide layer) that directly contacts the semiconductor layer structure 160, one or more optional adhesion and or barrier metal layers, one or more bulk metal layers, and the source pads 104. Typically, the source pads 104 are a part of a bulk metal layer that is exposed through the protective layer 109. Herein, the source metallization 190 will be illustrated as a single layer for simplicity, but it will be appreciated that it typically includes multiple layers and may have any appropriate form. The source metallization 190 may generally overlie or correspond to an “active region” 107 of the power MOSFET 100 where the unit cell transistors are located. An inactive region 108 of power MOSFET 100 surrounds the active region 107. The inactive region 108 may include a termination region that extends around the periphery of the MOSFET 100 that includes guard rings, junction termination elements or other termination structures (not shown), a gate pad region that underlies the gate pad 102, and gate bus regions (discussed below).

Bond wires 101 are shown in FIG. 3A that may be used to connect the gate pad 102 and the source pads 104 to external circuits or the like. The drain pad 106 on the bottom side of power MOSFET 100 may be connected to an external circuit through, for example, an underlying submount (not shown).

FIG. 3B is another plan view of power MOSFET 100 with the polymide layer 109 omitted to expose the full source and gate metallization. As shown in FIG. 3B, the source metallization 190 extends throughout the active region 107 of the device. The gate metallization includes the gate pad 102 and a gate bus 103. The source metallization 190 is spaced apart from both the gate pad 102 and the gate bus 103 so that a single metal layer may be used to form the source metallization and the gate metallization. The gate pad 102 is spaced apart from the gate bus 103 so that the gate current may pass through one or more lumped gate resistors (not visible in the figures) that are formed underneath an intermetal dielectric layer 105. The lumped gate resistors may, for example, improve the electromagnetic interference (“EMI”) performance of the device and/or improve the stability of long feedback loops that are created as the lengths of the gate electrodes are increased in order to increase the power handling capability of the device. The metal gate buses 103 extend around much of the periphery of the active region 107. The gate buses 103 may provide a low resistance path for distributing gate signals that are applied to the gate pad to the gate electrodes 182 (see FIG. 3C) that extend throughout the active region 107.

FIG. 3C is the same view as FIG. 3B of power MOSFET 100 except that in FIG. 3C the source metallization 190 and the intermetal dielectric layer 105 are omitted to show the gate electrodes 182 that are formed in respective gate trenches 180 in the semiconductor layer structure 160. In the depicted MOSFET 100, the gate electrodes 182 extend horizontally across the semiconductor layer structure 160 (i.e., in the x-direction). In other cases, the gate electrodes 182 may extend vertically across the semiconductor layer structure 160, or both horizontally-extending and vertically-extending gate electrodes 182 can be provided to form a grid-like gate electrode structure. The gate electrodes 182 may be connected to the gate pad 102 through the gate buses 103. The gate electrodes 182 may comprise, for example, a doped polysilicon pattern.

FIG. 3D is an enlarged view of the portion of the plan view of FIG. 3C in the box labelled 3D. FIG. 3E is a schematic cross-sectional view taken along line 3E-3E of FIG. 3D with an intermetal dielectric layer and source metallization 190 that are omitted in FIGS. 3C-3D added for context in FIG. 3E.

As can be seen in FIG. 3D, the gate trenches 180 are formed in the upper surface of the semiconductor layer structure 160. A longitudinal axis of each gate trench extends in the x-direction. A thin gate oxide layer 170, which is typically a silicon oxide layer, lines the sidewalls and bottom of each gate trench 180. A gate electrode 182, which is typically a highly-doped polysilicon gate electrode 182, is formed within each gate trench 180 on the gate oxide layer 170. The gate oxide layer 170 insulates the gate electrode 182 from the semiconductor layer structure 160. The gate trenches 180 (and hence the gate oxide layers 170 and gate electrodes 182) extend in parallel to each other in the x-direction. N-type source regions 140 are formed in the upper surface of the semiconductor layer structure 160 on either side of each gate trench 180. P-type regions are formed midway in between adjacent gate trenches 180. In the depicted embodiment, the p-type regions comprise separately implanted p-type contact regions 136 that have a higher p-type doping concentration than the p-wells 130. While the p-type contact regions 136 are shown as longitudinal stripes of p-type material that extend in the same direction as the gate trenches 180 (i.e., the x-direction), it will be appreciated that embodiments of the present invention are not limited thereto. For example, in other embodiments, the p-type contact regions 136 may comprise “islands” of p-type material that are formed within a continuous source region 140 that extends between adjacent gate trenches 180. In other embodiments, the source regions 140 and the p-type contact regions 136 may comprise alternating stripes of n-type and p-type material, where these stripes extend in the y-direction.

Referring next to the cross-sectional view of FIG. 3E, the unit cell structure of power MOSFET 100 is shown in more detail. As shown in FIG. 3E, power MOSFET 100 includes an n-type silicon carbide semiconductor substrate 110. The substrate 110 may comprise, for example, a single crystal 4H silicon carbide semiconductor substrate that is heavily-doped with n-type impurities (i.e., an n+ silicon carbide substrate). The impurities may comprise, for example, nitrogen or phosphorous. In example embodiments, the n-type substrate 110 may have a doping concentration of, for example, between 1×10¹⁸ atoms/cm³ and 1×10²¹ atoms/cm³, although other doping concentrations may be used. The substrate 110 may be relatively thick in some embodiments (e.g., 20-100 microns or more). The substrate 110 may be partially or fully removed in some embodiments. It should be noted that while the substrate 110 is depicted as a relatively thin layer, this is done to allow enlarging the thickness of other layers and regions in FIG. 3E, and it will be appreciated that the substrate 110 will typically be much thicker than shown.

A lightly-doped n-type (n-) silicon carbide drift layer 120 is provided on an upper surface of the substrate 110. The drift layer 120 may also be referred to herein as a drift region 120. Typically, the drift layer 120 is formed via an epitaxial growth process and is doped during growth. The n-type drift region 120 may have, for example, a doping concentration of 1×10¹⁴ to 5×10¹⁷ dopants/cm³, with the doping level typically selected based on a blocking voltage rating of the device. In the depicted embodiment, the n-type drift region 120 has a doping concentration of about 1×10¹⁶ dopants/cm³. The n-type drift region 120 may be a thick region, having a vertical height above the substrate 110 of, for example, 3-50 microns. The drift region 120 does not include a more heavily-doped JFET region 122 in this embodiment.

The drift layer 120 and the substrate 110 together act as a common drain region for the power MOSFET 100. The drain pad 106 is formed on the substrate 110 opposite the drift region 120.

A plurality of moderately-doped (p) p-type silicon carbide well regions 130 (which may also be referred to herein as a “p-wells 130”) are formed on the upper surface of the n-type drift region 120. The moderately-doped (p) p-type silicon carbide well regions 130 are deep p-wells 130 that extend deeper into the semiconductor layer structure 160 than the gate trenches 180. As discussed above, the deep p-wells 130 may be formed using a channeled ion implantation process so that the deep p-wells 130 are channeled ion implant p-wells 130. The p-wells 130 may, for example, have a peak doping concentration of about 1×10¹⁷ dopants/cm³ or 2×10¹⁷ dopants/cm³. The p-wells may extend at least as deep into the semiconductor layer structure 160 as the gate trenches 180, and typically will extend deeper into the semiconductor layer structure 160 than the gate trenches 180 (e.g., 0.1 to 0.7 microns deeper or 0.2 to 0.5 microns deeper in example embodiments). Upper surfaces of the deep p-wells 130 contact the respective source regions 140. The p-wells 130 may, in some case, be formed by implanting p-type dopant ions into selected portions of the drift region 120, but are not considered to be part of the drift region 120 as the dopant ions convert the portions of the drift region 120 into one or more distinct p-wells 130.

The above-discussed n-type source regions 140 are formed on or in upper portions of the respective deep p-wells 130. Each source region 140 may extend, for example, to a maximum depth of between 0.2 microns and 1.0 microns from the upper surface of the semiconductor layer structure 160. The source regions 140 are heavily-doped n-type (n+) silicon carbide source regions 140. For example, the source regions 140 may have a peak doping concentration that exceeds 1×10²⁰ dopants/cm³. The heavily-doped n-type silicon carbide source regions 140 may be formed by ion implantation.

The substrate 110, the drift region 120, the p-wells 130 (including the channel regions 132 which are discussed below) and the source regions 140, together comprise the semiconductor layer structure 160 of power MOSFET 100.

As noted above, a plurality of gate trenches 180 are formed in the upper portion of the semiconductor layer structure 160. Each gate trench 180 may, for example, extend to a maximum depth of between 0.5 microns and 1.5 microns from the upper surface of the semiconductor layer structure 160. While only one full gate trench 180 and a portion of a second gate trench 180 are shown in the cross-section of FIG. 3E, it will be appreciated from FIG. 3C that power MOSFET 100 may include a large number of gate trenches 180. The gate trenches 180 may be formed via an etching process.

A gate oxide layer 170 is provided in each gate trench 180 to cover the sidewalls and bottom surface of the gate trench 180. Each gate oxide layer 170 may comprise, for example, a silicon oxide (SiO₂) pattern. The gate oxide layers 170 may be formed generally conformally within the respective gate trenches 180.

A gate electrode 182 is formed in each gate trench 180 on the gate oxide layer 170. The gate electrodes 182 may comprise a conductive material such as a silicide (e.g., NiSi, TiSi, WSi, CoSi), a metal (e.g., Ti, Ta or W), a metal nitride (e.g., TiN, TaN or WN) or a doped semiconductor material (e.g., doped polycrystalline silicon). The gate oxide layers 170 may insulate the gate electrodes 182 from the semiconductor layer structure 160, thereby preventing the gate electrodes 182 from short circuiting to the semiconductor layer structure 160. Each gate electrode 182 may connect to one of the gate buses 103 (see FIGS. 3B-3C). In the depicted embodiment, the gate electrodes 182 are recessed so that the upper surface of each gate electrode 182 is below an upper surface of the semiconductor layer structure 160. It will be appreciated that in other embodiments the gate electrodes 182 may extend above and onto the upper surface of the semiconductor layer structure 160, with the gate oxide layer 170 insulating the gate electrodes 182 from the upper surface of the semiconductor layer structure 160.

Intermetal dielectric layers 172 are formed that cover each gate electrode 182. The intermetal dielectric layers 172 insulate the source metallization 190 from the gate electrodes 182.

The source metallization 190 is formed on the upper surface of the semiconductor layer structure 160 and on the intermetal dielectric layers 172. The source metallization 190 may comprise at least a source contact (e.g., a metal silicide layer) that forms ohmic contacts with the semiconductor layer structure 160 and a bulk metallization layer on the source contact layer. Additional metal layers may be provided including, for example, one or more adhesion layers and/or one or more diffusion barrier layers.

The portions of each deep p-well 130 that are adjacent a gate trench 180 act as channel regions 132 during on-state operation. In particular, when appropriate bias voltages are applied to the gate, drain and source terminals 102, 104, 106 of power MOSFET 100, a conductive n-type inversion layer is formed in the portion of each deep p-well 130 that is adjacent a gate electrode 182 (i.e., in the channel regions 132) will be inverted, allowing current to flow through the channel regions 132. Thus, a current path is created between the source and drain terminals 104, 106 that flows through the source metallization 190, the source regions 140, the channel regions 132, the drift region 120, the substrate 110 and the drain contact 106. The power MOSFET 100 may be turned off by changing the applied bias voltages (typically by lowering or removing the gate bias voltage).

As can be seen from FIG. 3E, since power MOSFET 100 has relatively narrow JFET gaps 124, the deep p-wells 130 may be sufficient for shielding the gate oxide layers 170 in the gate trenches 180 from high electric field values during reverse blocking operation. This is particularly true as the channel regions 132 in the deep p-wells 130 may have a higher doping concentration than is conventional, which provides enhanced electric field suppression in the adjacent JFET gaps 124. In addition, the pitch of power MOSFET 100 may be very small, such as a pitch of 1 to 3 microns (where the pitch is the distance between the centers of adjacent gate trenches 180). Each deep p-well 130 may extend continuously from a left side of a first gate trench 180 to a right side of an adjacent gate trench 180.

As discussed above, the deep p-wells 130 may be formed using a channeled ion implantation process. As such, the depth of each deep p-well 130 may be substantially constant, with the only variation in depth being the natural variation attributable to ion implantation. As such, a variation in depth along a lower surface of each p-well 130 may be less than 0.2 microns, less than 0.15 microns or less than 0.1 microns in example embodiments. Herein, the depth of each deep p-well 130 is considered to be “substantially constant” if the depth varies by less than 0.2 microns.

Still referring to FIG. 3E, pursuant to some embodiments of the present invention, a semiconductor device 100 is provided that comprises a semiconductor layer structure 160 that comprises a drift layer 120 having a first conductivity type (here n-type), first and second gate trenches 180 in the semiconductor layer structure 160, and a first well region 130 that forms a first sidewall of the first gate trench 180 and a first sidewall of the second gate trench 180. The first well region 130 comprises a channel region, and the first well region 130 extends deeper into the semiconductor layer structure 160 than the first gate trench 180 and the depth of each deep p-well 130 may be substantially constant.

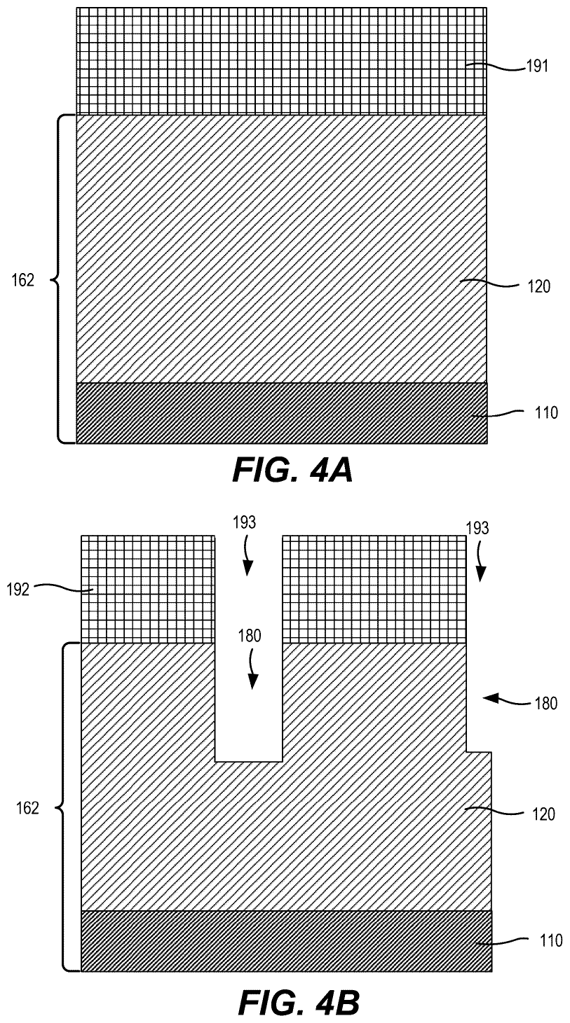

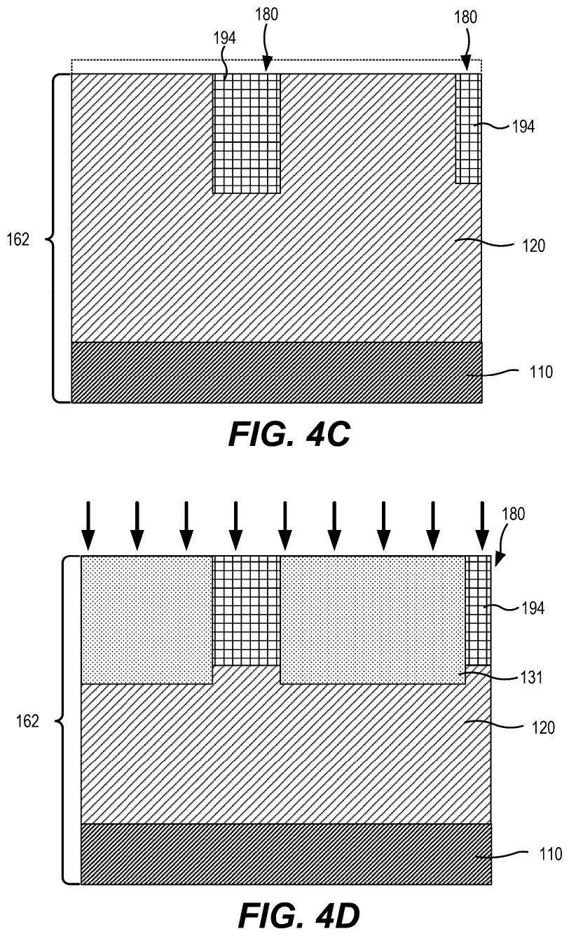

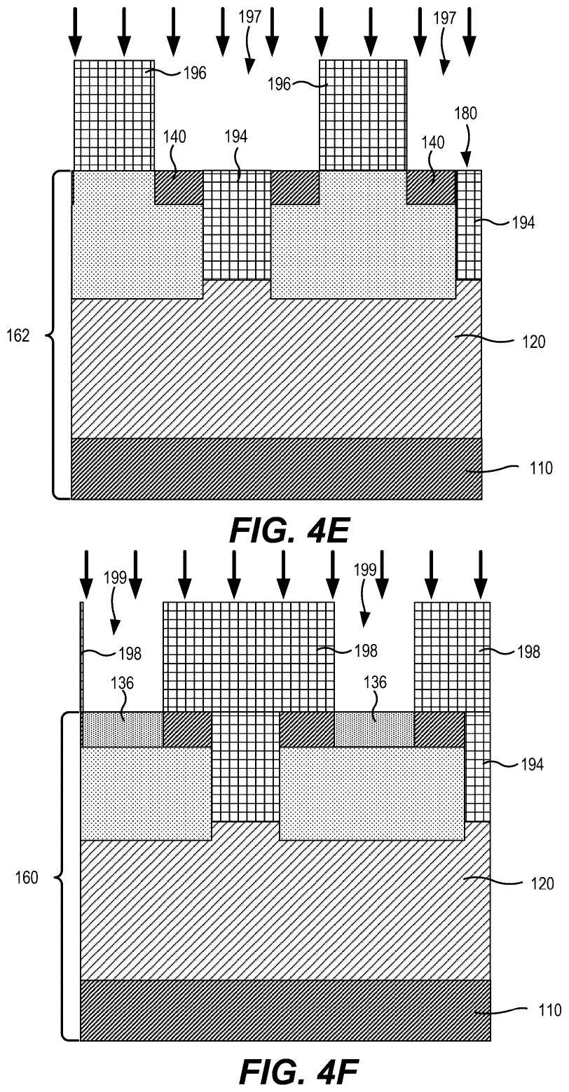

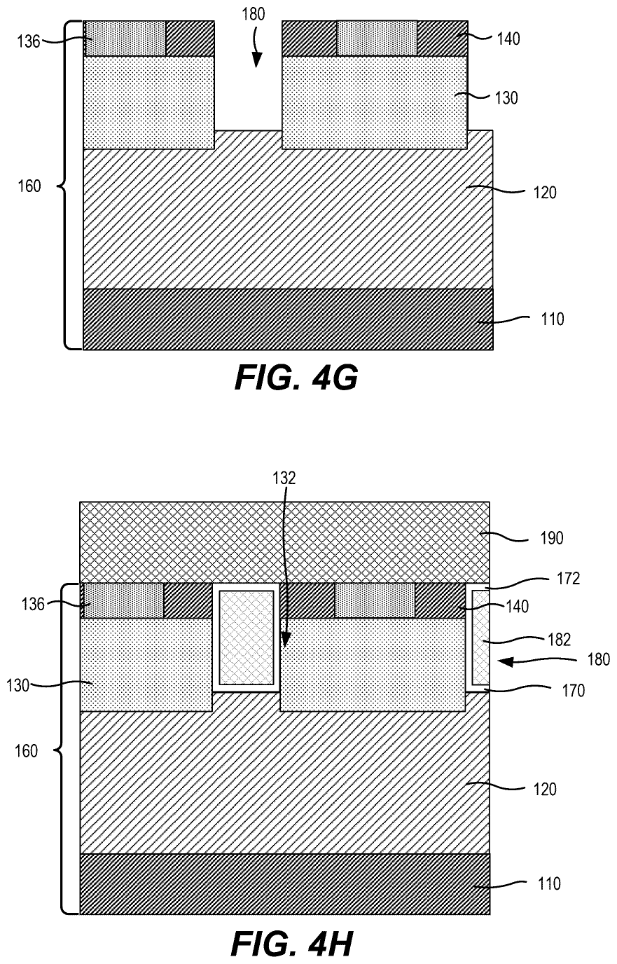

FIGS. 4A-4H are a series of schematic cross-sectional diagrams that illustrate a method of fabricating the power MOSFET 100 of FIGS. 3A-3E.

As shown in FIG. 4A, the n-type silicon carbide drift layer 120 may be grown on the n-type silicon carbide substrate 110 via epitaxial growth to form a preliminary semiconductor layer structure 162. Typically, the drift layer 120 is doped n-type during epitaxial growth. Typically the entire drift layer 120 is doped n-type, although embodiments of the present invention are not limited thereto. For example, the upper portion of the drift layer 120 may be undoped or doped p-type in other embodiments. A first mask layer 191 is formed on the upper surface of the preliminary semiconductor layer structure 162. The first mask layer 191 may comprise, for example, a silicon oxide layer. A wide variety of other known mask materials may be used to form the first mask layer 191 (as well as the other mask layers and patterns discussed herein).

Referring to FIG. 4B, the first mask layer 191 is patterned (e.g., using standard photolithography processes) to form a first patterned mask 192. The first patterned mask 192 includes a plurality of openings 193 in locations where the gate trenches 180 are to be formed. An etching process is then performed to etch the gate trenches 180 into the upper surface of the preliminary semiconductor layer structure 162 using the first patterned mask 192 as an etch mask.

Referring to FIG. 4C, the first patterned mask 192 is removed (e.g., using a stripping processes). Then a second mask layer (not shown) is formed on the upper surface of the preliminary semiconductor layer structure 162. The second mask layer is formed to a thickness that is sufficient to fill (or at least mostly fill) the gate trenches 180. A planarization process may then be performed so that only portions of the second mask layer that are in the gate trenches 180 remain after the planarization process is performed. The remaining portions of the second mask layer form a second patterned mask 194 which, as shown in FIG. 4C, may only be present in the gate trenches 180. In other embodiments, the planarization process may merely thin and planarize the second mask layer so that a relatively thin layer of mask material extends on the upper surface of the preliminary semiconductor layer structure 162. The dotted line in FIG. 4C illustrates the additional material that is included in the second mask pattern 194 in this alternate embodiment.

Referring to FIG. 4D, an ion implantation process is then performed to implant p-type dopants into upper portions of preliminary semiconductor layer structure 162 to form preliminary p-wells 131 in the preliminary semiconductor layer structure 162. A channeled ion implantation process may be used to form the preliminary p-wells 131 in some embodiments. As shown, the p-type dopants may be blanket implanted throughout the active area. The channeled ion implantation process allows the preliminary p-wells 131 to be formed as deep structures that extend deeper into the preliminary semiconductor layer structure 162 than the gate trenches 180. The p-type dopants also are implanted into the second patterned mask 194 that is present in each of the gate trenches 180. The second patterned mask 194 may be formed of, for example, silicon oxide or polysilicon. The ion implantation angles that provide for channeled ion implantation into the silicon carbide will not result in channeled ion implantation in the material used to from the second patterned mask 194. As such, channeling will only occur with respect to the dopant ions implanted into the silicon carbide of the preliminary semiconductor layer structure 162, and the dopant ions will implant as a random (normal) ion implantation into the second patterned mask 194. Since random implants do not implant nearly as deeply as channeled implants for a given implantation energy level, the p-type dopant ions do not implant all the way through the second mask pattern 194 (which is subsequently removed). Consequently, the preliminary p-wells 131 may be formed to extend deeper into the preliminary semiconductor layer structure 162 than the gate trenches 180 while also ensuring that the portions of the drift region 120 that are directly below the gate trenches 180 are not implanted with p-type dopants (or at least only implanted at background doping levels).

In other embodiments, the preliminary p-wells 131 may be formed using a high-energy random ion implantation process. When a random ion implantation technique is used, it may be necessary to thicken the portions of the second patterned mask 194 that are above the gate trenches 180 or to use a material for the second patterned mask 194 that is more resistant to ion implantation.

Referring to FIG. 4E, a third mask layer (not shown) may then be formed on the upper surface of the preliminary semiconductor layer structure 162. The third mask layer may comprise, for example, a silicon oxide layer. The third mask layer is then patterned (e.g., using standard photolithography processes) to form a third patterned mask 196. The third patterned mask 196 includes a plurality of openings 197 in locations where the source regions 140 are to be formed. The third patterned mask 196 may (optionally) also leave the gate trenches 180 exposed. Next, an ion implantation process is performed to implant n-type dopants into selected portions of the preliminary p-wells 131 to form the source regions 140. The n-type dopants also are implanted into the second patterned mask 194 that is present in each of the gate trenches 180. The ion implantation process used to form the source regions 140 may be a low-energy, high dose random ion implantation process.

Referring to FIG. 4F, the third patterned mask 196 may then be removed (e.g., using a stripping process). Next, a fourth mask layer (not shown) may be formed on the upper surface of the preliminary semiconductor layer structure 162. The fourth mask layer may comprise, for example, a silicon oxide layer. The fourth mask layer is then patterned (e.g., using standard photolithography processes) to form a fourth patterned mask 198. The fourth patterned mask 198 includes a plurality of openings 199 in locations where the p-type contact regions 136 are to be formed. Next, an ion implantation process is performed to implant p-type dopants into selected portions of the preliminary p-wells 131 to form the p-type contact regions 136 and to convert the preliminary p-wells 131 into the deep p-wells 130. The ion implantation process used to form the p-type contact regions 136 may be a low-energy, high dose random ion implantation process. Formation of the p-type contact regions 136 may complete formation of the semiconductor layer structure 160.

Referring to FIG. 4G, the second patterned mask 194 and the fourth patterned mask 198 may then be removed.

Referring to FIG. 4H, a gate oxide layer 170 may next be formed in each gate trench 180, and then gate electrodes 182 may be formed in the gate trenches 180 on the respective gate oxide layers 170. An intermetal dielectric layer 172 may then be formed to cover the upper surfaces of the gate electrodes 182. Finally, the source metallization may be deposited to complete the power MOSFET 100.

Conventionally, when p-wells are formed by ion implantation in gate-trench power semiconductor devices, they are formed before the gate trenches are etched into the upper surface of the semiconductor layer structure. In contrast, in the above-described method, the gate trenches 180 are formed before the p-wells 130, and the p-wells 130 are formed using a channeled ion implantation process with mask material deposited into each gate trench 180. This allows the p-wells 130 to be formed deeper than the gate trenches 180 while also ensuring that p-type dopants are not implanted into the portions of the drift layer 120 that are immediately below the gate trenches 180 so that those region retain n-type conductivity.

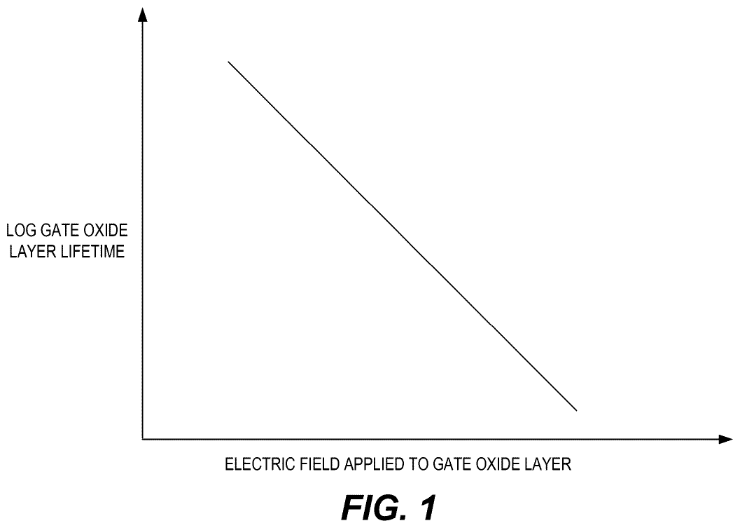

FIGS. 3A-3E illustrate one example power MOSFET 100 according to embodiments of the present invention. FIGS. 5, 8, 1-110 and 13-14 are schematic cross-sectional view of a gate trench silicon carbide power MOSFET according to further embodiments of the present invention. The cross-sections of FIGS. 5, 8, 1-110 and 13-14 are each taken along a line equivalent to line 3E-3E of FIG. 3D. The power MOSFETs of FIGS. 5, 8, 1-110 and 13-14 may each have the design shown in FIGS. 3A-3D, except os otherwise noted below.

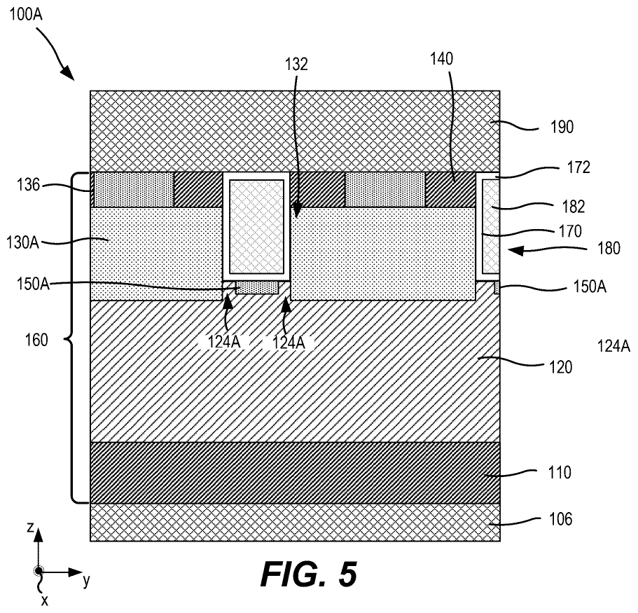

Referring to FIG. 5, a power MOSFET 100A is shown that is very similar to power MOSFET 100, with the primary difference being that power MOSFET 100A further includes a p-type trench shield 150A below each gate trench 180. Each trench shield 150A may be a p-type region that is formed in the drift layer 120. Each p-type trench shield 150A may, for example, extend underneath a respective one of the gate trenches 180 for all or substantially all of the length of the gate trench 180. As shown, the upper surface of each trench shield 150A may form a central portion of the bottom of each gate trench 180. The p-type trench shields 150A may be moderately doped (p⁺) silicon carbide regions. The peak doping concentration of each trench shield 150A may be, for example, between about 5×10¹⁷ dopants/cm³ and 5×10¹⁹ dopants/cm³.

The addition of the trench shields 150 converts the single JFET gap 124 provided beneath each gate trench 180 of power MOSFET 100 into a pair of significantly narrower JFET gaps 124A in power MOSFET 100A. This may increase current crowding during on-state operation, which increases the on-state resistance of power MOSFET 100A as compared to power MOSFET 100 (all else being equal). The trench shields 150A may significantly increase electric field suppression in the gate oxide layers 170 during reverse blocking operation, which may improve the reliability of power MOSFET 100A as compared to power MOSFET 100 (all else being equal). In some embodiments, the depth of the p-wells 130A may be reduced as compared to the depth of p-wells 130A, which may help decrease the on-state resistance. Preferably, however, the p-wells 130A extend deeper into the semiconductor layer structure than the trench shields 150 so that any avalanche currents will be spread across the p-wells 130A.

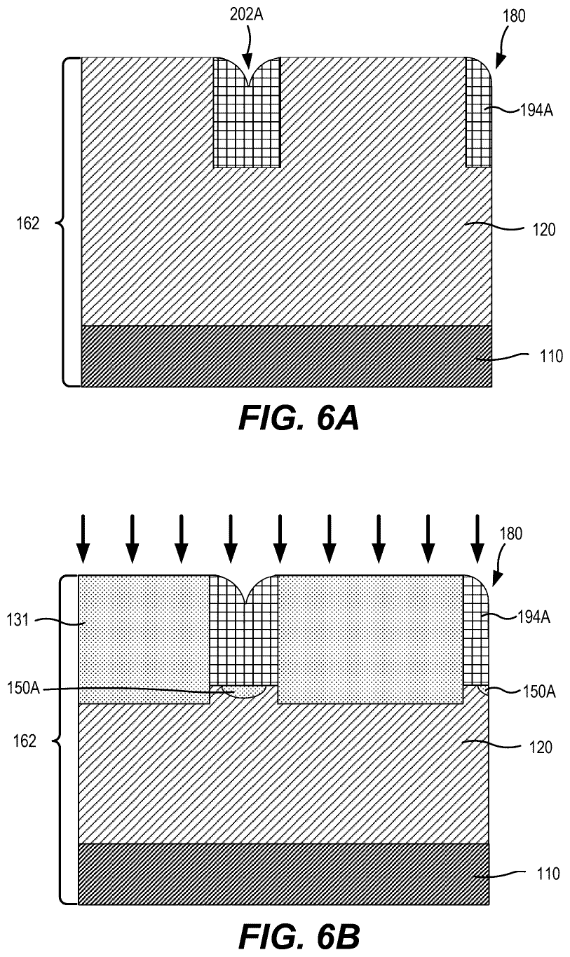

FIGS. 6A-6B are a pair of schematic cross-sectional diagrams that, in conjunction with FIGS. 4A-4H, illustrate a method of fabricating the power MOSFET 100A of FIG. 5.

Pursuant to this method, the operations discussed above with reference to FIGS. 4A and 4B may first be performed, and the first patterned mask 192 of FIG. 4B is removed. Next, referring to FIG. 6A, a second mask layer (not shown) is formed on the upper surface of the preliminary semiconductor layer structure 162. The second mask layer is formed to a thickness that mostly fills the gate trenches 180. A mask material is used that is sufficiently viscous so that the second mask layer includes “recesses” 202A that are formed along the longitudinal axis of each gate trench 180. A planarization process is then be performed so that portions of the second mask layer that are outside of the gate trenches 180 are removed, thereby converting the second mask layer into a second patterned mask 194A, as shown in FIG. 6A.

Referring to FIG. 6B, an ion implantation process is then performed to implant p-type dopants into upper portions of preliminary semiconductor layer structure 162 to form preliminary p-wells 131 in the preliminary semiconductor layer structure 162. A channeled ion implantation process may be used to form the preliminary p-wells 131 in some embodiments. As shown, the p-type dopants may be blanket implanted throughout the active area. The channeled ion implantation process allows the preliminary p-wells 131 to be formed as deep structures that extend deeper into the preliminary semiconductor layer structure 162 than the gate trenches 180. The p-type dopants also are implanted into the second patterned mask 194A that is present in each of the gate trenches 180. The ion implantation energy may be set so that p-type dopants that are implanted into the recessed portions of the second mask pattern 194A will implant all the way through the second mask pattern 194A to form a plurality of trench shields 150A underneath the central portions of the respective gate trenches 180. The thicker portions of the second mask pattern 194A in the outer portions of the gate trenches 180 may be sufficient to prevent the p-type dopants ions from implanting into the portions of drift region 120 that are under the outer portions of each gate trench 180, as shown.

The operations discussed above with reference to FIGS. 4E through 4H may then be performed to complete fabrication of power MOSFET 100A.

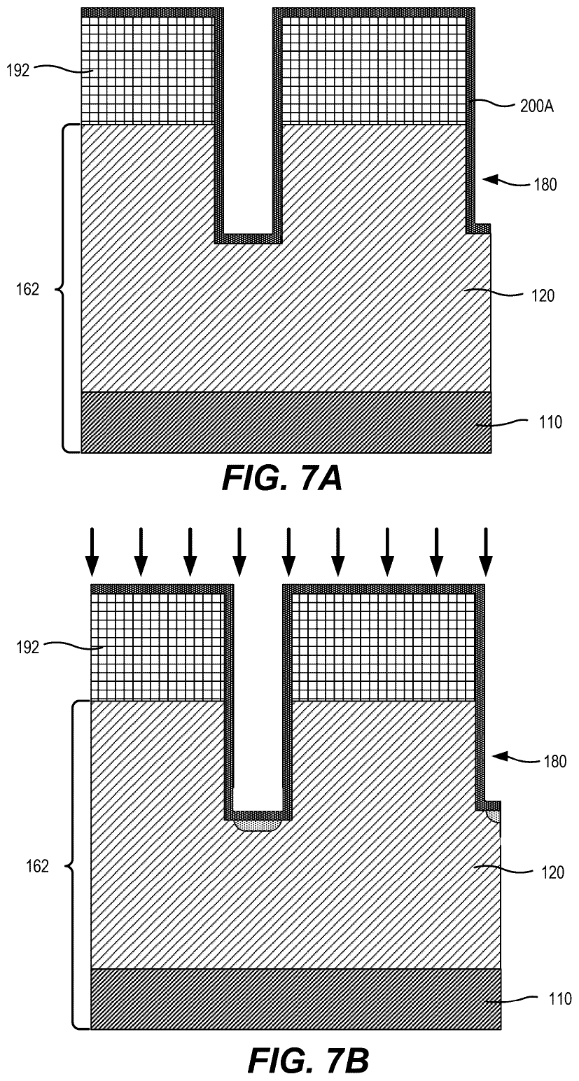

FIGS. 7A-7B are a pair of schematic cross-sectional diagrams that, in conjunction with FIGS. 4A-4H, illustrate an alternative method of fabricating the semiconductor device of FIG. 5.

Pursuant to this method, the operations discussed above with reference to FIGS. 4A and 4B may first be performed. Next, referring to FIG. 7A, a fifth mask layer 200A may be conformally formed on the first mask pattern 192 and within the gate trenches 180. As shown in FIG. 7A, the fifth mask layer 200A may be a conformal layer that coats the sidewalls and bottoms of each gate trench 180.

Referring to FIG. 7B, an ion implantation process is then performed to implant p-type dopants into the drift layer 120 underneath the center portion of each gate trench 180 to form the p-type trench shields 150A. The ion implantation process used to form the p-type trench shields 150A may be a low-energy, high dose ion implantation process. The portions of the fifth mask layer 200A that are on the sidewalls of the gate trenches 180 prevent the p-type dopants from being implanted underneath the lower corners of the gate trenches 180 to ensure that the channel regions 132 in the later-formed deep p-wells 130A electrically connect to the drift region 120. The fifth mask layer 200A may then be removed, and the operations discussed above with reference to FIGS. 4C through 4H may then be performed to complete fabrication of power MOSFET 100A.

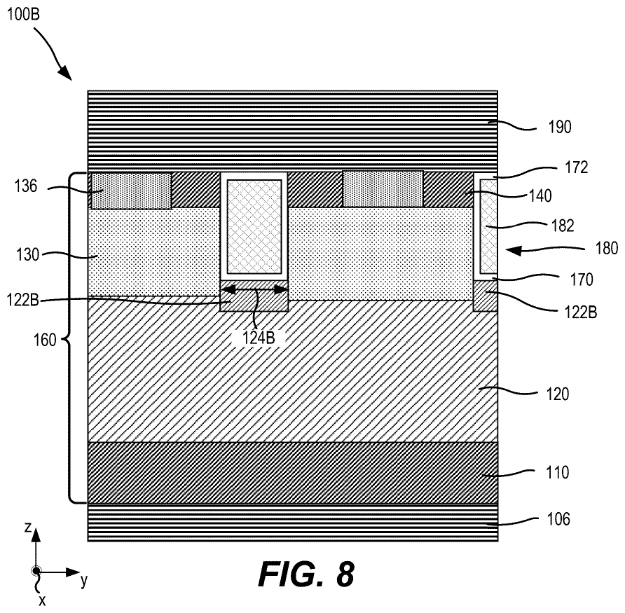

FIG. 8 is a schematic cross-sectional view of a gate trench silicon carbide power MOSFET 100B according to further embodiments of the present invention that is taken along a line equivalent to line 3E-3E of FIG. 3D.

Referring to FIG. 8, the power MOSFET 100B is very similar to power MOSFET 100, with the only difference being that power MOSFET 100B further includes an n-type JFET region 122B below each gate trench 180. Each JFET region 122B is an n-type region in an upper portion of the drift layer 120 that has a higher peak doping concentration than the remainder of the drift region 120. In example embodiments, the JFET regions 122B may have a peak doping concentration that is between twice and ten times the peak doping concentration of the lower portion of the drift layer 120. The JFET regions 122B are considered to be part of the drift layer 120, and have a higher doping concentration than the remainder of the drift region 120. The JFET regions 122B may each have a relatively constant doping concentration or may have graded doping concentrations. In example embodiments, the peak doping concentration of each JFET region 122B may be between 1×10¹⁶ dopants/cm³ and 5×10¹⁷ dopants/cm³. The upper surface of each JFET region 122B may (but need not) form the bottom surface of a respective one of the gate trenches 180. The JFET regions 122B may (but need not) extend deeper into the semiconductor layer structure 160 than the deep p-wells 130 in some embodiments. For example, each JFET region 122B may extend between 0.05 and 0.25 microns deeper into the semiconductor layer structure 160 than the deep p-wells 130. In other embodiments, the JFET regions 122B and the deep p-wells 130 may extend to the same depth into the semiconductor layer structure 160 or the deep p-wells 130 may extend deeper into the semiconductor layer structure 160 than the JFET regions 122B. In some embodiments, each JFET region 122B may have a thickness in the depth direction of between 0.2 and 0.8 microns or between 0.2 and 0.5 microns.

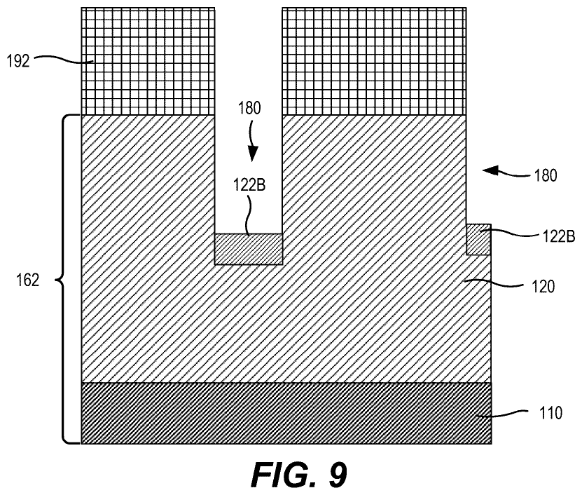

As will be discussed in more detail with reference to FIG. 9, the JFET regions 122B may be formed via ion implantation using the mask pattern that is used to etch the gate trenches 180 as an ion implantation mask during the formation of the JFET regions 122B. Consequently, the JFET regions 122B may be self-aligned with the gate trenches 180. Since the JFET regions 122B have a higher doping concentration, they help to reduce the on-state resistance of power MOSFET 100B as compared to power MOSFET 100. This higher doping concentration is provided in the JFET gaps 124B where current crowding occurs, and helps to more efficiently spread the on-state current out into the drift layer 120.

As shown in FIG. 8, pursuant to certain embodiments of the present invention, a semiconductor device 100B is provided that comprises a semiconductor layer structure 160 that comprises a drift layer 120 having a first conductivity type (here n-type), a first well region 130 having a second conductivity type (here p-type), a second well region 130 having the second conductivity type, and a JFET region 122B having the first conductivity type. The JFET region 122B has a doping concentration that is higher than a doping concentration of the drift layer 120. A gate trench 180 is provided in the semiconductor layer structure 160. The first well region 130 forms a first sidewall of the gate trench 180 and the second well region 130 forms a second sidewall of the gate trench 180. Additionally, first and second sidewalls of the JFET region 122B are aligned with respective first and second sidewalls of the gate trench 180.

In some embodiments, the first and second well regions 130 each extend deeper into the semiconductor layer structure 160 than the gate trench 180. In some embodiments, the first and second well regions 130 have substantially planar lower surfaces. In some embodiments, the JFET region 122B extends deeper into the semiconductor layer structure 160 than both the first and second well regions 130. In some embodiments, the first and second well regions 130 may each be channeled ion implant well regions.

FIG. 9 is a schematic cross-sectional diagram that, in conjunction with FIGS. 4A-4H, illustrates a method of fabricating the power MOSFET 100B of FIG. 8.

To form the power MOSFET 100B of FIG. 8, the operations discussed above with reference to FIGS. 4A and 4B may first be performed. Next, referring to FIG. 9, an ion implantation process is performed using the first patterned mask 192 as an ion implantation mask to form the JFET regions 122B in the upper portion of the drift layer 120. Each JFET region 122B is formed below a respective one of the gate trenches 180 and is self-aligned with the gate trenches 180. The first patterned mask 192 may then be removed. The operations of FIGS. 4C through 4H may then be performed (note that FIGS. 4C-4H do not show the JFET regions 122B, but they will be present in this embodiment).

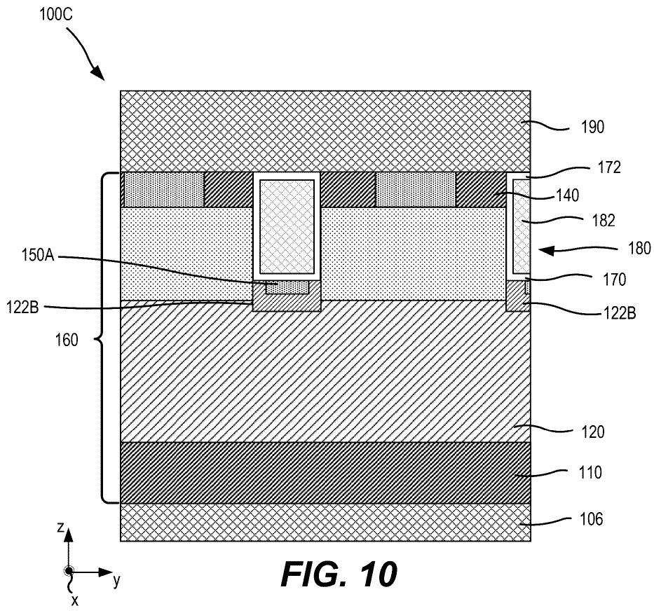

FIG. 10 is a schematic cross-sectional view of a gate trench silicon carbide power MOSFET 100C according to other embodiments of the present invention that is taken along a line equivalent to line 3E-3E of FIG. 3D. As can be seen by comparing FIG. 10 to FIGS. 5 and 8, the power MOSFET 100C adds the JFET regions 122B of power MOSFET 100B to power MOSFET 100A. Thus, power MOSFET 100C may be identical to power MOSFET 100 of FIGS. 3A-3E except that power MOSFET 100C further includes both the trench shields 150 of power MOSFET 100A and the JFET regions 122B of power MOSFET 100B. As the structure and functions of the trench shields 150 and the JFET regions 122B have been discussed above, further description thereof will be omitted here. Power MOSFET 100C may be fabricated by combining the above-discussed fabrication techniques for power MOSFETs 100A and 100B

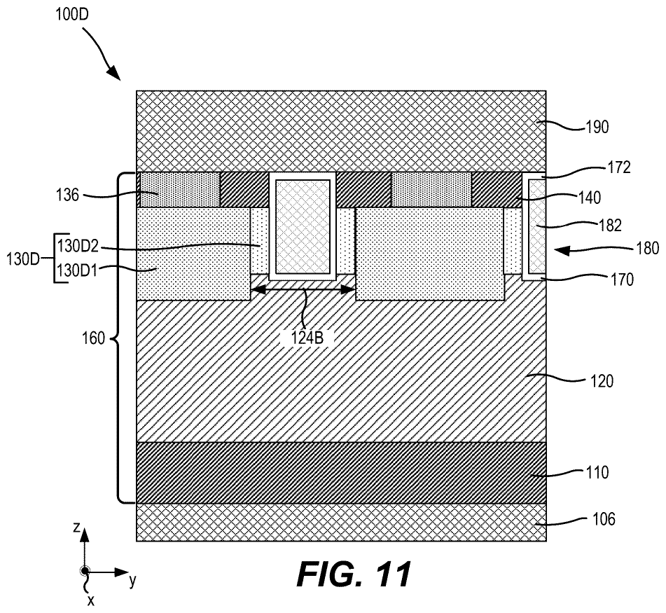

FIG. 11 is a schematic cross-sectional view of a gate trench silicon carbide power MOSFET 100D according to still further embodiments of the present invention that is taken along a line equivalent to line 3E-3E of FIG. 3D.

Referring to FIG. 11, it can be seen that the power MOSFET 100D is shown that again is similar to power MOSFET 100, except that power MOSFET 100D includes p-wells 130D that comprise both deep p-wells 130D1 as well as “shallow” p-wells 130D2. The deep p-wells 130D1 may have the same depth and doping concentration as the deep p-wells 130 of power MOSFET 100. The deep p-wells 130D1 may, however, have a shorter lateral (y-direction) width than the deep p-wells 130 of power MOSFET 100 to make room for the shallow p-wells 130D2. The “shallow” p-wells 130D2 are deeper than most conventional p-wells, but are referred to herein as “shallow” p-wells 130D2 because they are shallower than the deep p-wells 130D1. The “shallow” p-wells 130D2 may, for example, extend to about the same depth into the semiconductor layer structure 160 as the gate electrodes 182 in some embodiments, and in other embodiments to about the same depth into the semiconductor layer structure 160 as the gate trenches 180. The peak doping concentration of the shallow p-wells 130D2 may be less than the doping concentration of the deep p-wells 130D1 in some embodiments. The doping concentration of the shallow p-wells 130D2 may, for example, be set to a value that optimizes on-state performance of the MOSFET 100D.

Power MOSFET 100D may not suppress electric fields during reverse blocking operation as well as power MOSFET 100 since the more lightly doped and shallower p-wells 130D2 that are adjacent the gate trenches 180 will tend to suppress electric fields less than the deep p-wells 130 of power MOSFET 100. As shown in FIG. 11, the deep p-wells 130D1 may be formed somewhat deeper into the semiconductor layer structure 160 than the deep p-wells 130 of power MOSFET 100 to improve the electric field suppression. Since the shallow p-wells 130D2 may not extend as deep as the gate trenches 180, the JFET gaps 124D may be wider than the corresponding JFET gaps 124 of power MOSFET 100. This may reduce the on-state resistance of power MOSFET 100D as compared to power MOSFET 100.

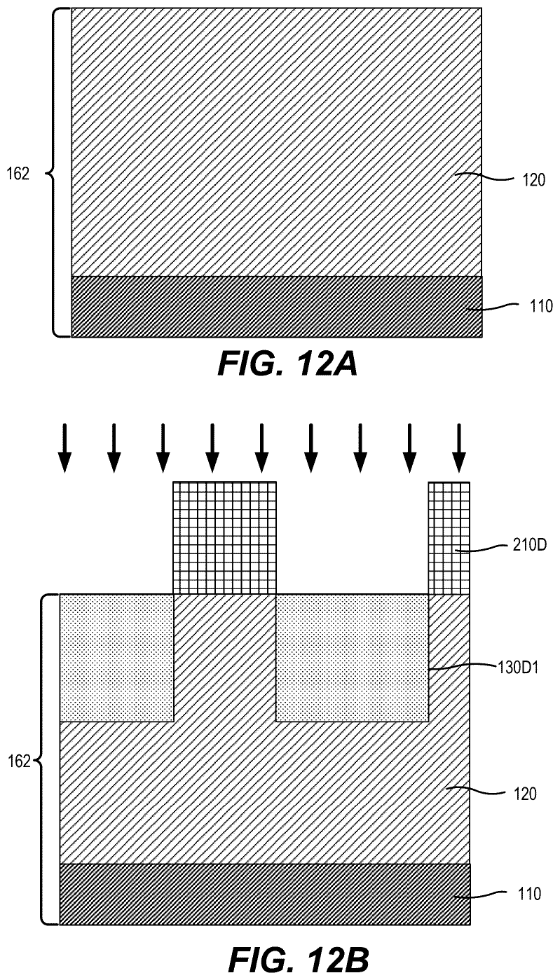

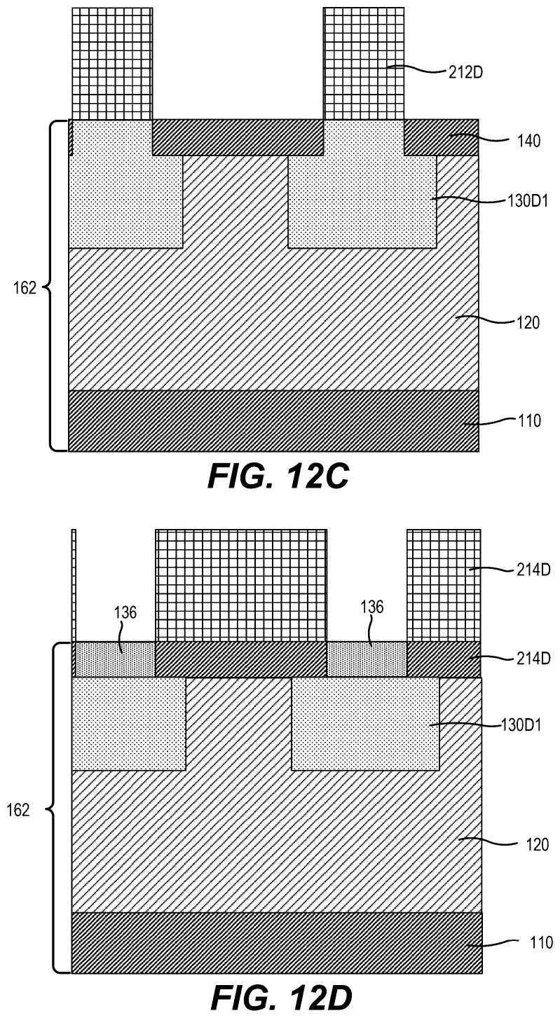

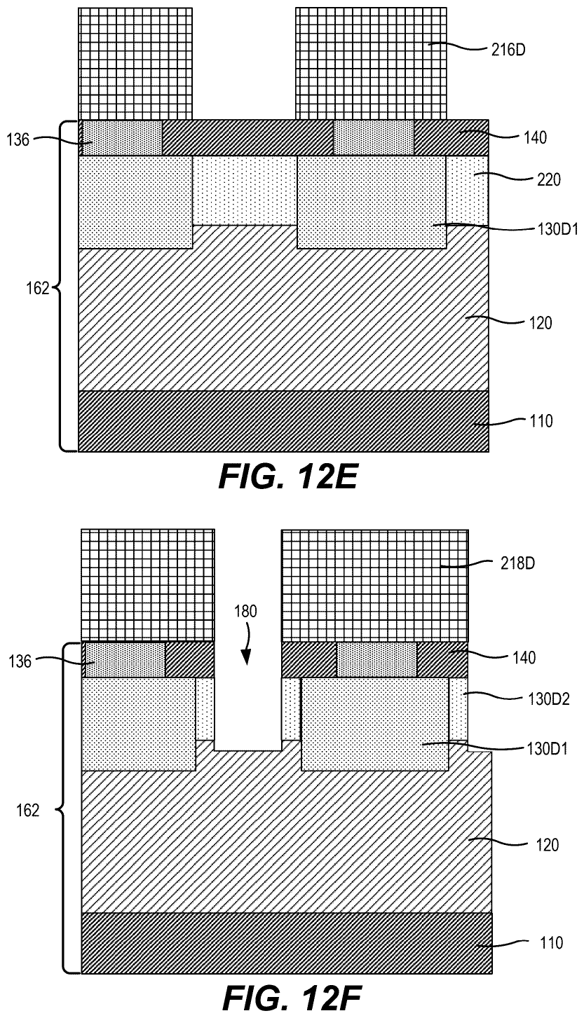

FIGS. 12A-12F are a series of schematic cross-sectional diagrams that illustrate a method of fabricating the poqwe MOSFET 100D of FIG. 11.

As shown in FIG. 12A, the n-type silicon carbide drift layer 120 may be grown on the n-type silicon carbide substrate 110 via epitaxial growth to form a preliminary semiconductor layer structure 162 in the same manner discussed above with reference to FIG. 4A.

Referring to FIG. 12B, a first patterned mask 210D is formed on the upper surface of the preliminary semiconductor layer structure 162. The first patterned mask 210D covers locations where gate trenches 180 and the shallow p-wells 130D2 will be formed in subsequent processing steps. Next, the deep p-wells 130D1 are formed via ion implantation. A channeled ion implantation process or a random ion implementation process may be used to form the deep p-wells 130D1.

Referring to FIG. 12C, the first patterned mask 210D is removed. Next, a second patterned mask 212D is then formed on the upper surface of the preliminary semiconductor layer structure 162. Next, source regions 140 are formed via ion implantation using the second mask pattern 212D as an ion implantation mask. The second patterned mask 212D is then removed.

Referring to FIG. 12D, a third patterned mask 214D is then formed on the upper surface of the preliminary semiconductor layer structure 162. Next, the p-contact regions 136 are formed via ion implantation using the third mask pattern 214D as an ion implantation mask. The third patterned mask 214D is then removed.

Referring to FIG. 12E, a fourth patterned mask 216D is then formed on the upper surface of the preliminary semiconductor layer structure 162. Next, p-type regions 220 are formed via ion implantation using the fourth mask pattern 216D as an ion implantation mask. The fourth patterned mask 216D is then removed.

Referring to FIG. 12F, a fifth patterned mask 218D is formed that exposes regions where the gate trenches 180 are to be formed. An etching process is then performed to form the gate trenches 180. This etching process removes central portions of each p-type region 220, thereby forming the shallow p-wells 130D2. The shallow p-wells 130D2 will form the channel regions in power MOSFET 100D. The fifth patterned mask 218D is then removed.

The operations discussed above with reference to FIG. 4H may then be performed to complete fabrication of power MOSFET 100D.

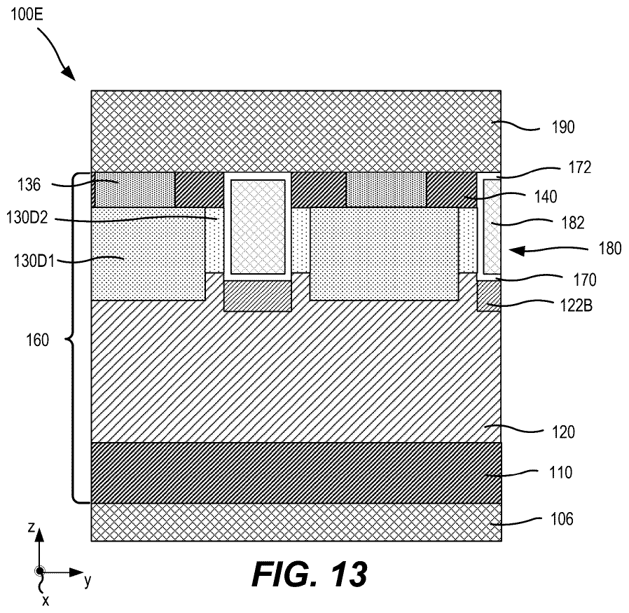

FIG. 13 is a schematic cross-sectional view of a gate trench silicon carbide power MOSFET 100E according to yet additional embodiments of the present invention that is taken along a line equivalent to line 3E-3E of FIG. 3D. As can be seen by comparing FIG. 13 to FIG. 8, the power MOSFET 100E adds the JFET regions 122B of power MOSFET 100B to power MOSFET 100D. Thus, power MOSFET 100E may be identical to power MOSFET 100 of FIGS. 3A-3E except that power MOSFET 100E further includes both the shallow p-wells 130D2 of power MOSFET 100D and the JFET regions 122B of power MOSFET 100B. As the structure and functions of the shallow p-wells 130D2 and the JFET regions 122B have been discussed above, further description thereof will be omitted here. Power MOSFET 100E may be fabricated by combining the above-discussed fabrication techniques for power MOSFETs 100B and 100D. Note that since the ion implantation steps used in the formation of power MOSFET 100D are performed before the gate trenches 180 are formed, the ion implantation that is used to form the JFET regions 122B will be formed after the other ion implantation steps in the fabrication of power MOSFET 100E.

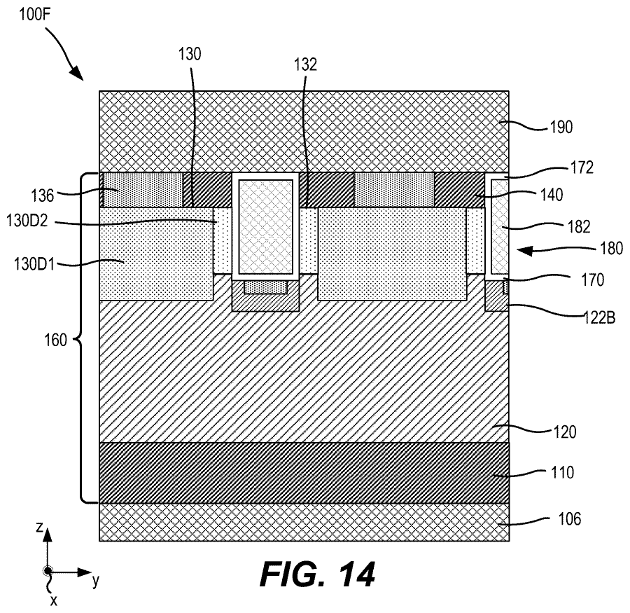

FIG. 14 is a schematic cross-sectional view of a gate trench silicon carbide power MOSFET 100F according to still other embodiments of the present invention that is taken along a line equivalent to line 3E-3E of FIG. 3D. As can be seen by comparing FIG. 14 to FIG. 13, the power MOSFET 100F adds the trench shields 150A of power MOSFET 100A to power MOSFET 100E. As the structure and functions of the trench shields 150A have been discussed above, further description thereof will be omitted here. Power MOSFET 100F may be fabricated by combining the above-discussed fabrication techniques for power MOSFETs 100A and 100E.

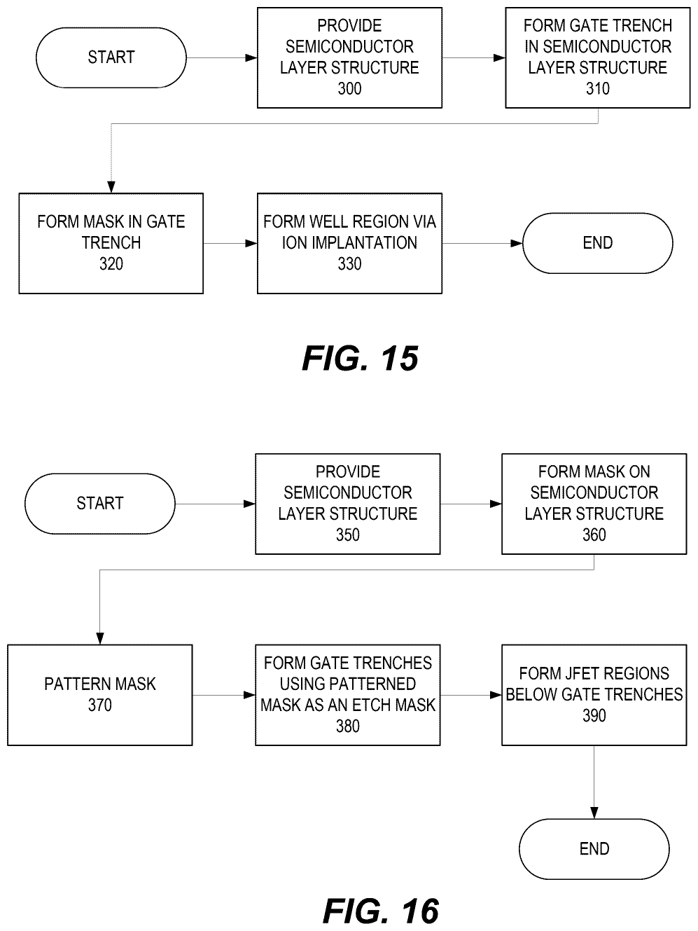

FIG. 15 is a flow chart of a method of fabricating a semiconductor device according to certain embodiments of the present invention. As shown in FIG. 15, operations may begin with forming or otherwise providing a semiconductor layer structure that comprises a drift layer having a first conductivity type (Block 300). Next, a gate trench is formed in the semiconductor layer structure (Block 310). Then an ion implantation mask is formed in the gate trench (Block 320). Finally, an ion implantation process is performed to form a well region in the semiconductor layer structure that has a second conductivity type using the mask in the gate trench as an ion implantation mask (Block 330). The ion implantation process may be a channeled ion implantation process that forms p-wells that are deeper than the gate trench without implanting dopant ions below the gate trench.

FIG. 16 is a flow chart of a method of fabricating a semiconductor device according to further embodiments of the present invention. As shown in FIG. 16, operations may begin with forming or otherwise providing a semiconductor layer structure that comprises a drift layer having a first conductivity type (Block 350). Next, a first mask layer is formed on the semiconductor layer structure Block 360). The first mask layer is then patterned to provide a first patterned mask (Block 370). Next, a plurality of gate trenches are formed in the semiconductor layer structure using the first patterned mask as an etch mask (Block 380). Finally, first conductivity type dopants are implanted into the semiconductor layer structure to form a plurality of JFET regions underneath the respective gate trenches, where each JFET regions has a doping concentration that is higher than a doping concentration of the drift layer (Block 390).

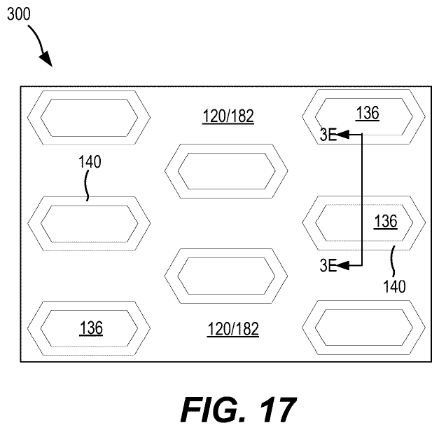

FIG. 17 is a plan view of a gate trench silicon carbide power MOSFET 300 according to still further embodiments of the present invention. Power MOSFETs 100 and 100A-100F each have gate trenches, gate electrodes, well regions and source regions that extend as parallel longitudinal stripes in the upper surface of the semiconductor layer structure. Power MOSFETs and other power semiconductor devices are also known that have the source regions (with the p-type contact regions therein) appear as spaced-apart islands within a continuous gate trench. islands and are not suitable for use in MOSFETs having well regions that are formed as a plurality of smaller spaced-apart islands within, for example, a continuous JFET region. Power MOSFETs having well regions formed as spaced-apart islands are referred to as having a “cell configuration,” whereas power MOSFETs having gate trenches, gate electrodes, well regions and source regions that extend as parallel longitudinal stripes are referred to as having a “stripe configuration.” MOSFETs having cell configurations may provide higher cell (or MOS channel) packing density than MOSFETs having the more conventional stripe configuration. It will be appreciated that the techniques according to embodiments of the present invention that are disclosed herein may be used to form cell configuration power semiconductor devices, and that each of the above-discussed power MOSFET's may be implemented to have a cell configuration.

By way of example, FIG. 17 is a plan view of the semiconductor layer structure of a power MOSFET 300 that is a cell configuration version of the power MOSFET 100 of FIGS. 3A-3E. In FIG. 17, the source metallization 190, the gate electrodes 182, the gate oxide layer 170 and the intermetal dielectric layer 172 are omitted to illustrate the upper surface of the semiconductor layer structure 160 with the gate trenches 180 formed therein.

As shown in FIG. 17, a single, continuous gate trench 180 may extend throughout the active region. A plurality of source regions 140 appear as small islands that are each surrounded by the continuous gate trench 180. A p-type contact region 136 is formed within each source region 140. The deep p-wells are positioned below the source regions/p-type contact regions 136, 140, and hence are not visible in FIG. 17. The portions of the drift region 120 that form the bottoms of the gate trenches 182 are visible in the view of FIG. 17. In the depicted embodiment, the source regions 140 are formed as irregular hexagonal islands. It will be appreciated that the source regions 140 may have a wide variety of different shapes, including square, rectangular, regular hexagonal, octagonal, circular, etc. in other embodiments. It will also be appreciated that the gate trenches may alternatively be formed as the islands within a continuous source region in other embodiments.

A cross-section of power MOSFET 300 taken along line 3E-3E of FIG. 17 may be essentially identical to FIG. 3E. As such, a separate cross-section for power MOSFET 300 is not provided herein. It will be appreciated that each of power MOSFETs 100A-100F may be implemented to have a cell configuration, and that the cross-sectional views of those power MOSFETs discussed above accurately represent unit cell configurations.

In the description above, each example embodiment has a certain conductivity type. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure (e.g., MOSFET, IGBT, etc.).

The present invention has primarily been discussed above with respect to silicon carbide based power semiconductor devices. It will be appreciated, however, that silicon carbide is used herein as an example and that the devices discussed herein may be formed in any appropriate wide band-gap semiconductor material system. As an example, gallium nitride based semiconductor materials (e.g., gallium nitride, aluminum gallium nitride, etc.) may be used instead of silicon carbide in any of the embodiments described above.

References are made herein to a first element extending deeper into a semiconductor layer structure of a gate trench semiconductor device than a second element. The depth that an element extends into a semiconductor layer structure refers to a distance that the element extends from an upper surface of the semiconductor layer structure, where the upper surface is the surface from which the gate trenches extend into the semiconductor layer structure. Thus, if a first element extends deeper into a semiconductor layer structure than a second element, this means that a lowermost surface of the first element is farther from the upper surface of the semiconductor layer structure than is a lowermost surface of the second element. In the embodiments discussed above, the depth is the distance in the z-direction from the uppermost surface of the semiconductor layer structure.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

Herein, the term “plurality” means two or more. Herein, “substantially” means within +/−10% unless otherwise indicated.

As used herein, two elements of a semiconductor device are considered to “vertically overlap” if an axis that is perpendicular to the major surfaces of a semiconductor layer structure of the semiconductor device intersects both elements.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Embodiments of the invention are also described with reference to a flow chart. It will be appreciated that the steps shown in the flow chart need not be performed in the order shown.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments of the invention and, although specific terms are employed, they are used in a generic and descriptive sense only and not for purposes of limitation, the scope of the invention being set forth in the following claims.

1. A semiconductor device, comprising:
a semiconductor layer structure that comprises a drift layer having a first conductivity type, wherein an upper portion of the drift layer comprises a JFET region having the first conductivity type, where the JFET region has a doping concentration that is higher than a doping concentration of a lower portion of the drift layer; and
a gate trench that has a first sidewall and a second sidewall in the semiconductor layer structure,
wherein first and second sidewalls of the JFET region are aligned with respective first and second sidewalls of the gate trench.

2. The semiconductor device of claim 1, further comprising a first well region having a second conductivity type that comprises a first portion of the first sidewall of the gate trench and a second well region having the second conductivity type that comprises a first portion of the second sidewall of the gate trench.

3. The semiconductor device of claim 2, wherein the first well region and the second well region each extend deeper into the semiconductor layer structure than the gate trench.

4. (canceled)

5. The semiconductor device of claim 2, wherein the JFET region extends deeper into the semiconductor layer structure than the first well region and extends deeper into the semiconductor layer structure than the second well region.

6. The semiconductor device of claim 2, wherein the first well region comprises a first channeled ion implant well region and the second well region comprises a second channeled ion implant well region.

7. The semiconductor device of claim 2, wherein the first well region comprises a first deep well region that extends at least as deep into the semiconductor layer structure as the gate trench and a first shallow well region that is laterally adjacent the first deep well region and that does not extend as deep into the semiconductor layer structure as the first deep well region.

8. The semiconductor device of claim 7, wherein a peak doping concentration of the first deep well region is greater than a peak doping concentration of the first shallow well region.

9. The semiconductor device of claim 2, wherein the semiconductor layer structure further comprises a trench shield having the second conductivity type below the gate trench, wherein the first and second well regions extend deeper into the semiconductor layer structure than the trench shield.

10. (canceled)

11. The semiconductor device of claim 2, wherein the first well region and the second well region are part of a continuous well region and the gate trench is one of a plurality of gate trenches that appear as islands in the semiconductor layer structure when the semiconductor device is viewed from above, and wherein the continuous well region forms sidewalls of each of the gate trenches.

12. A semiconductor device, comprising:
a semiconductor layer structure that comprises a drift layer having a first conductivity type;
a gate trench that has a first sidewall and an opposed second sidewall in the semiconductor layer structure;
a gate oxide layer in the gate trench; and
a well region that comprises a channel region,
wherein the channel region extends at least as deep into the semiconductor layer structure as the gate trench, and
wherein the gate oxide layer directly contacts the drift region underneath outer portions of a bottom of the gate trench.

13. The semiconductor device of claim 12, wherein a lower surface of the well region has a substantially constant depth.

14. The semiconductor device of claim 12, wherein an upper portion of the drift layer structure further comprises a JFET region underneath the first gate trench, the JFET region having the first conductivity type and a doping concentrations that is higher than a doping concentration of a lower portion of the drift layer, wherein sidewalls of the JFET region are aligned with sidewalls of the first gate trench.

15. The semiconductor device of claim 14, wherein the JFET region extends deeper into the semiconductor layer structure than the well region.

16-18. (canceled)

19. The semiconductor device of claim 12, wherein the well region is part of a continuous well region and the gate trench is one of a plurality of gate trenches that appear as islands in the semiconductor layer structure when the semiconductor device is viewed from above, and wherein the continuous well region forms sidewalls of each of the gate trenches.

20. A semiconductor device, comprising:
a semiconductor layer structure; and
a gate trench in the semiconductor layer structure,
wherein the semiconductor layer structure comprises:
a drift layer having a first conductivity type, where an upper portion of the drift layer comprises a JFET region having the first conductivity type and a doping concentration that is higher than a doping concentration of a lower portion of the drift layer,
wherein first and second sidewalls of the JFET region are aligned with respective first and second sidewalls of the gate trench.

21. The semiconductor device of claim 20, wherein the semiconductor layer structure further comprises a first well region and a second well region that each extend deeper into the semiconductor layer structure than the gate trench.

22. The semiconductor device of claim 21, wherein the first and second well regions have substantially planar lower surfaces.

23. (canceled)

24. The semiconductor device of claim 21, wherein the first well region comprises a first channeled ion implant well region and the second well region comprises a second channeled ion implant well region.

25. The semiconductor device of claim 20, wherein the semiconductor layer structure comprises a first well region comprises a first deep well region that extends at least as deep into the semiconductor layer structure as the gate trench and a first shallow well region that is laterally adjacent the first deep well region and that does not extend as deep into the semiconductor layer structure as the first deep well region.

26. (canceled)

27. The semiconductor device of claim 21, wherein the semiconductor layer structure further comprises a trench shield having the second conductivity type below the gate trench, wherein the first and second well regions extend deeper into the semiconductor layer structure than the trench shield.

28-58. (canceled)

59. The semiconductor device of claim 20, wherein the JPET region forms at least a portion of a bottom of the gate trench.
